(19) United States
(12) Patent Application Publication
(10) Pub. No.: US 2026/0164793 A1
(43) Pub. Date: Jun. 11, 2026

(54) Array Substrate, Display Panel and Display Device

(71) Applicants: BEIJING BOE TECHNOLOGY DEVELOPMENT CO., LTD., Beijing (CN); BOE TECHNOLOGY GROUP CO., LTD., Chaoyang District, Beijing (CN)

(72) Inventors: Song Cui, Beijing (CN); Tuo Sun, Beijing (CN); Huijuan Zhang, Beijing (CN); Libin Liu, Beijing (CN)

(21) Appl. No.: 18/711,739

(22) PCT Filed: Aug. 25, 2023
(86) PCT No.: PCT/CN2023/114937

§ 371 Date: May 20, 2024

(51) Int. Cl. H10D 86/40; H10K 59/121

(52) U.S. Cl. CPC H10D 86/421; H10K 59/1213

(57) ABSTRACT

An array substrate includes sub-pixel regions, each sub-pixel region is provided with a pixel driving circuit therein; the pixel driving circuit includes first-type transistors and second-type transistors, and the second-type transistors include at least a writing transistor. The array substrate includes a base substrate, a first active film layer disposed on the base substrate, a second active film layer disposed on a side of the first active film away from the base substrate, and a third source-drain metal layer disposed on a side of the second active film layer away from the base substrate. The first active film layer includes active later patterns of the first-type transistors. The second active film layer includes an active layer pattern of the writing transistor; the third source-drain metal layer includes data signal line, and the active layer pattern of the writing transistor is electrically connected to a data signal line.

### CROSS-REFERENCE TO RELATED APPLICATION

This application is the United States national phase of International Patent Application No. PCT/CN2023/114937, filed Aug. 25, 2023, the disclosure of which is hereby incorporated by reference in its entirety.

### BACKGROUND OF THE INVENTION

### Field of the Invention

The present disclosure relates to the field of display technologies, and in particular, to an array substrate, a display panel and a display device.

### Description of Related Art

At present, organic light-emitting diode (OLED) display apparatuses have been widely used due to their characteristics such as self-luminescence, quick response, wide viewing angle, being capable of being manufactured on flexible substrates. An OLED display apparatus includes a plurality of sub-pixels; each sub-pixel includes a pixel driving circuit and a light-emitting device, and the light-emitting device is driven by the pixel driving circuit to emit light to achieve display function.

### SUMMARY OF THE INVENTION

In an aspect, an array substrate is provided. The array substrate includes a plurality of sub-pixel regions, each sub-pixel region is provided with a pixel driving circuit therein, a plurality of pixel driving circuits are arranged in rows and columns; the pixel driving circuit includes a plurality of first-type transistors and a plurality of second-type transistors, the plurality of second-type transistors include at least a writing transistor. The array substrate includes a base substrate, a first active film layer, a second active film layer and a third source-drain metal layer; the first active film layer is disposed on a side of the base substrate, and the first active film layer includes active layer patterns of the plurality of first-type transistors; the second active film layer is disposed on a side of the first active film layer away from the base substrate, and the second active film layer includes an active layer pattern of the writing transistor; the third source-drain metal layer is disposed on a side of the second active film layer away from the base substrate, the third source-drain metal layer includes data signal lines, and the active layer pattern of the writing transistor is electrically connected to a data signal line.

In some embodiments, the array substrate further includes: a first source-drain metal layer disposed between the first active film layer and the second active film layer, and a second source-drain metal layer disposed between the second film layer and the third source-drain metal layer. In the sub-pixel region, the second source-drain metal layer includes a data line transfer pattern; the data signal line is connected to the data line transfer pattern through a via hole, and the data line transfer pattern is connected to the active layer pattern of the writing transistor.

In some embodiments, the pixel driving circuit further includes a capacitor. The array substrate further includes a first gate metal layer and a second gate metal layer that are sequentially arranged on the side of the first active film layer away from the base substrate. In the sub-pixel region, the first gate metal layer includes a first plate pattern of the capacitor, and the second gate metal layer includes a second plate pattern of the capacitor. The third source-drain metal layer further includes first voltage signal lines. In the sub-pixel region, the second source-drain metal layer further includes a first transfer pattern, and the first source-drain metal layer includes a first bridging pattern; a first voltage signal line is connected to the first transfer pattern in the second source-drain metal layer through a via hole, and the first transfer pattern is connected to the first bridging pattern in the first source-drain metal layer through another via hole, and the first bridging pattern is connected to the second plate pattern in the second gate metal layer through yet another via hole, so that the first voltage signal line is electrically connected to the second plate pattern.

In some embodiments, the second-type transistors further include a first reset transistor and a compensation transistor, and the first-type transistors include a driving transistor, a first light-emitting control transistor, a second light-emitting control transistor and a second reset transistor.

The first active film layer includes an active layer pattern of the driving transistor, an active layer pattern of the first light-emitting control transistor, an active layer pattern of the second light-emitting control transistor, and an active layer pattern of the second reset transistor; the second active film layer further includes an active layer pattern of the first reset transistor and an active layer pattern of the compensation transistor.

In some embodiments, the array substrate further includes: a first source-drain metal layer disposed between the first active film layer and the second active film layer, a third gate metal layer disposed between the first source-drain metal layer and the second active film layer, and a fourth gate metal layer disposed on a side of the second active film layer away from the third gate metal layer. The third gate metal layer includes a first reset signal line first branch line and a scanning signal line first branch line; the first reset signal line first branch line passes through the active layer pattern of the first reset transistor, and the scanning signal line first branch line passes through both the active layer pattern of the compensation transistor and the active layer pattern of the writing transistor. The fourth gate metal layer includes a first reset signal line second branch line and a scanning signal line second branch line; the first reset signal line second branch line passes through the active layer pattern of the first reset transistor, and the scanning signal line second branch line passes through both the active layer pattern of the compensation transistor and the active layer pattern of the writing transistor. The first reset signal line first branch line is electrically connected to the first reset signal line second branch line, and the scanning signal line first branch line is electrically connected to the scanning signal line second branch line.

In some embodiments, the array substrate further includes a second gate metal layer disposed on the side of the first active film layer away from the base substrate, a first source-drain metal layer disposed between the first active film layer and the second active film layer, and a second source-drain metal layer disposed between the second active film layer and the third source-drain metal layer. The second gate metal layer includes a plurality of initialization signal lines. In the sub-pixel region, the first source-drain metal layer includes a second bridging pattern, and the second source-drain metal layer includes a second transfer pattern. The second bridging pattern is electrically connected to the active layer pattern of the second reset transistor and an initialization signal line through two via holes, so that the active layer pattern of the second reset transistor is electrically connected to the initialization signal line; the second transfer pattern is connected to the second bridging pattern and the active layer pattern of the first reset transistor through another two via holes, so that the active layer pattern of the first reset transistor is electrically connected to the initialization signal line.

In some embodiments, the array substrate further includes a first gate metal layer disposed between the first active film layer and the second gate metal layer; in the sub-pixel region, the first source-drain metal layer further includes a third bridging pattern, and the second source-drain metal layer further includes a third transfer pattern. The third bridging pattern is connected to a first plate pattern of a capacitor in the first gate metal layer through a via hole, the third transfer pattern is connected to the third bridging pattern through another via hole, and the active layer pattern of the compensation transistor in the second active film layer is connected to the third transfer pattern through yet another via hole, so that the compensation transistor is electrically connected to the first plate pattern.

In some embodiments, in the sub-pixel region, the first source-drain metal layer further includes a fourth bridging pattern, and the second source-drain metal layer further includes a fourth transfer pattern. The fourth bridging pattern is connected to the active layer pattern of the second light-emitting control transistor in the first active film layer through a via hole; the fourth transfer pattern is connected to the fourth bridging pattern through a via hole, and the active layer pattern of the compensation transistor in the second active film layer is connected to the fourth transfer pattern through another via hole, so that the compensation transistor is electrically connected to the second light-emitting control transistor.

In some embodiments, in the sub-pixel region, the first source-drain metal layer further includes a fifth bridging pattern, and the second source-drain metal layer further includes a fifth transfer pattern. The fifth bridging pattern is connected to the active layer pattern of the first light-emitting control transistor in the first active film layer through a via hole; the fifth transfer pattern is connected to the fifth bridging pattern through another via hole, and the active layer pattern of the writing transistor in the second active film layer is connected to the fifth transfer pattern through yet another via hole, so that the writing transistor is electrically connected to the first light-emitting control transistor.

In some embodiments, in the sub-pixel region, the first source-drain metal layer further includes a sixth bridging pattern, and the second source-drain metal layer further includes a sixth transfer pattern. The sixth bridging pattern is connected to the active layer pattern of the second light-emitting control transistor in the first active film layer through a via hole, and the sixth transfer pattern is connected to the sixth bridging pattern.

In some embodiments, four adjacent sub-pixel regions of the plurality of sub-pixel regions in a row direction are respectively a first sub-pixel region, a second sub-pixel region, a third sub-pixel region and a fourth sub-pixel region. Film layer patterns in every two adjacent sub-pixel regions are arranged in a mirror-image manner.

In some embodiments, the first-type transistors include a first light-emitting control transistor and a second reset transistor. An active layer pattern of a first light-emitting control transistor in the first sub-pixel region overlaps with an active layer pattern of a first light-emitting control transistor in the second sub-pixel region, and an active layer pattern of a second reset transistor in the second sub-pixel region overlaps with an active layer pattern of a second reset transistor in the third sub-pixel region.

In some embodiments, the array substrate further includes a first source-drain metal layer disposed between the first active film layer and the second active film layer; in the sub-pixel region, the first source-drain metal layer includes a first bridging pattern and a second bridging pattern; a first bridging pattern in the first sub-pixel region coincides with a first bridging pattern in the second sub-pixel region, and a second bridging pattern in the second sub-pixel region coincides with a second bridging pattern in the third sub-pixel region.

In some embodiments, second bridging patterns in sub-pixel regions arranged in a column direction are connected in sequence.

In some embodiments, the second-type transistors further include a first reset transistor and a compensation transistor, and the second active film layer further includes an active layer pattern of the first reset transistor and an active layer pattern of the compensation transistor; in the sub-pixel region, the active layer pattern of the first reset transistor is connected to the active layer pattern of the compensation transistor, and the active layer pattern of the writing transistor is located on a side of the active layer pattern of the compensation transistor in the row direction; an active layer pattern of a first reset transistor in the second sub-pixel region is connected to an active layer pattern of a first reset transistor in the third sub-pixel region.

In some embodiments, the array substrate further includes a second source-drain metal layer disposed between the second active film layer and the third source-drain metal layer; the second source-drain metal layer includes first transfer patterns and second transfer patterns. A first transfer pattern in the first sub-pixel region overlaps with a first transfer pattern in the second sub-pixel region, and a second transfer pattern in the second sub-pixel region overlaps with a second transfer pattern in the third sub-pixel region.

In some embodiments, the third source-drain metal layer includes a plurality of first voltage signal lines, and each first voltage signal line is located in a column of sub-pixel regions. The first voltage signal line includes voltage patterns and voltage sub-lines that are alternately connected, a dimension of a voltage pattern in the row direction is greater than a dimension of a voltage sub-line in the row direction. A first voltage signal line in the second sub-pixel region overlaps with a first voltage signal line in the third sub-pixel region.

In some embodiments, the display substrate further includes a first planarization layer disposed between the first source-drain metal layer and the third gate metal layer, and a thickness of the first planarization layer is in a range of 1.5 μm to 2 μm, inclusive.

In some embodiments, the array substrate further includes a second planarization layer disposed between the second source-drain metal layer and the third source-drain metal layer; the third source-drain metal layer is connected to the second source-drain metal layer through a via hole penetrating through the second planarization layer.

In some embodiments, the first active film layer is a low temperature polysilicon layer, and the second active film layer is an oxide layer.

In another aspect, a display panel is provided. The display panel includes the array substrate as described in any of the embodiments of the above aspect.

In some embodiments, the display panel further includes: a third planarization layer disposed on a side of the third source-drain metal layer away from the base substrate, an anode layer disposed on the third planarization layer, the anode layer including a plurality of anodes, a pixel definition layer disposed on a side of the anode layer away from the base substrate; and spacers disposed on a side of the pixel definition layer away from the base substrate. The plurality of anodes are electrically connected to the third source-drain metal layer through via holes penetrating through the third planarization layer.

In yet another aspect, a display device is provided. The display device includes the display panel as described in any of the embodiments of the above aspect.

### BRIEF DESCRIPTION OF THE DRAWINGS

In order to describe technical solutions in the present disclosure more clearly, the accompanying drawings to be used in some embodiments of the present disclosure will be introduced briefly. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a plane view of a display device, in accordance with some embodiments of the present disclosure;

FIG. 2 is a plane view of a display panel, in accordance with some embodiments of the present disclosure;

FIG. 3 is a plane view of an array substrate, in accordance with some embodiments of the present disclosure;

FIG. 4 is a sectional view of an array substrate, in accordance with some embodiments of the present disclosure;

FIG. 5A is an equivalent circuit diagram of a pixel driving circuit, in accordance with some embodiments of the present disclosure;

FIG. 5B is a timing signal control diagram of a pixel driving circuit, in accordance with some embodiments of the present disclosure;

FIG. 6A is a diagram showing a film structure of a first active film layer in an array substrate, in accordance with some embodiments of the present disclosure;

FIG. 6B is a diagram showing a film structure of a first gate metal layer in an array substrate, in accordance with some embodiments of the present disclosure;

FIG. 6C is a diagram showing a film structure of a second gate metal layer in an array substrate, in accordance with some embodiments of the present disclosure;

FIG. 6D is a diagram showing a film structure of a first interlayer dielectric layer in an array substrate, in accordance with some embodiments of the present disclosure;

FIG. 6E is a diagram showing a film structure of a first source-drain metal layer in an array substrate, in accordance with some embodiments of the present disclosure;

FIG. 6F is a diagram showing a film structure of a third gate metal layer in an array substrate, in accordance with some embodiments of the present disclosure;

FIG. 6G is a diagram showing a film structure of a second active film layer in an array substrate, in accordance with some embodiments of the present disclosure;

FIG. 6H is a diagram showing a film structure of a fourth gate metal layer in an array substrate, in accordance with some embodiments of the present disclosure;

FIG. 6I is a diagram showing a film structure of a second interlayer dielectric layer in an array substrate, in accordance with some embodiments of the present disclosure;

FIG. 6J is a diagram showing a structure of via holes connecting a first source-drain metal layer and a second source-drain metal layer in an array substrate, in accordance with some embodiments of the present disclosure;

FIG. 6K is a diagram showing a film structure of a second source-drain metal layer in an array substrate, in accordance with some embodiments of the present disclosure;

FIG. 6L is a diagram showing a film structure of a second planarization layer in an array substrate, in accordance with some embodiments of the present disclosure;

FIG. 6M is a diagram showing a film structure of a third source-drain metal layer in an array substrate, in accordance with some embodiments of the present disclosure;

FIG. 6N is a diagram showing a structure of a third planarization layer in a display panel, in accordance with some embodiments of the present disclosure;

FIG. 6O is a diagram showing a structure of an anode layer in a display panel, in accordance with some embodiments of the present disclosure;

FIG. 7A is a diagram showing a connection structure between a second source-drain metal layer and a third source-drain metal layer in an array substrate, in accordance with some embodiments of the present disclosure;

FIG. 7B is a diagram showing a connection structure between a first source-drain metal layer and a second source-drain metal layer in an array substrate, in accordance with some embodiments of the present disclosure;

FIG. 7C is a diagram showing a connection structure between a first source-drain metal layer and a first active film layer in an array substrate, in accordance with some embodiments of the present disclosure;

FIG. 7D is a diagram showing a connection structure between a second source-drain metal layer and a second active film layer in an array substrate, in accordance with some embodiments of the present disclosure;

FIG. 7E is a diagram showing a stacked arrangement structure of film layers in a display panel, in accordance with some embodiments of the present disclosure;

FIG. 8 is a diagram showing a stacked arrangement structure of film layers in a display panel, in accordance with some embodiments of the present disclosure;

FIG. 9A is a diagram showing a film arrangement structure of a first active film layer in an array substrate, in accordance with some embodiments of the present disclosure;

FIG. 9B is a diagram showing a film arrangement structure of a first gate metal layer in an array substrate, in accordance with some embodiments of the present disclosure;

FIG. 9C is a diagram showing a film arrangement structure of a second gate metal layer in an array substrate, in accordance with some embodiments of the present disclosure;

FIG. 9D is a diagram showing a film arrangement structure of a first interlayer dielectric layer in an array substrate, in accordance with some embodiments of the present disclosure;

FIG. 9E is a diagram showing a film arrangement structure of a first source-drain metal layer in an array substrate, in accordance with some embodiments of the present disclosure;

FIG. 9F is a diagram showing a film arrangement structure of a third gate metal layer in an array substrate, in accordance with some embodiments of the present disclosure;

FIG. 9G is a diagram showing a film arrangement structure of a second active film layer in an array substrate, in accordance with some embodiments of the present disclosure;

FIG. 9H is a diagram showing a film arrangement structure of a fourth gate metal layer in an array substrate, in accordance with some embodiments of the present disclosure;

FIG. 9I is a diagram showing a film arrangement structure of a second interlayer dielectric layer in an array substrate, in accordance with some embodiments of the present disclosure;

FIG. 9J is a diagram showing an arrangement structure of via holes connecting a first source-drain metal layer and a second source-drain metal layer in an array substrate, in accordance with some embodiments of the present disclosure;

FIG. 9K is a diagram showing a film arrangement structure of a second source-drain metal layer in an array substrate, in accordance with some embodiments of the present disclosure;

FIG. 9L is a diagram showing a film arrangement structure of a second planarization layer in an array substrate, in accordance with some embodiments of the present disclosure;

FIG. 9M is a diagram showing a film arrangement structure of a third source-drain metal layer in an array substrate, in accordance with some embodiments of the present disclosure;

FIG. 9N is a diagram showing a film arrangement structure of a third planarization layer, in accordance with some embodiments of the present disclosure; and

FIG. 9O is a diagram showing a film arrangement structure of an anode layer, in accordance with some embodiments of the present disclosure.

### DESCRIPTION OF THE INVENTION

The technical solutions in embodiments of the present disclosure will be described clearly and completely with reference to the accompanying drawings. Obviously, the described embodiments are merely some but not all of embodiments of the present disclosure. All other embodiments obtained on the basis of the embodiments of the present disclosure by a person of ordinary skill in the art shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, specific features, structures, materials, or characteristics described herein may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a plurality of” or “the plurality of” means two or more unless otherwise specified.

Some embodiments may be described using the terms “coupled”, “connected” and their derivatives. The term “connection” should be understood in a broad sense. For example, “connection” can be a fixed connection, a detachable connection, or an integrated connection; it can be a direct connection or an indirect connection through an intermediate medium. The term “coupled” indicates, for example, that two or more components are in direct physical or electrical contact. However, the term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

The phrase “applicable to” or “configured to” used herein means an open and inclusive expression, which does not exclude devices that are applicable to or configured to perform additional tasks or steps.

The term such as “about”, “substantially” or “approximately” as used herein includes a stated value and an average value within an acceptable range of deviation of a particular value determined by a person of ordinary skilled in the art, considering measurement in question and errors associated with measurement of a particular quantity (i.e., limitations of a measurement system).

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and areas of regions are enlarged for clarity. Variations in shape relative to the accompanying drawings due to, for example, manufacturing technologies and/or tolerances may be envisaged. Therefore, the exemplary embodiments should not be construed as being limited to the shapes of the regions shown herein, but including deviations due to, for example, manufacturing. For example, an etched region shown as a rectangle shape generally has a curved feature. Therefore, the regions shown in the accompanying drawings are schematic in nature, and their shapes are not intended to show actual shapes of regions in a device, and are not intended to limit the scope of the exemplary embodiments.

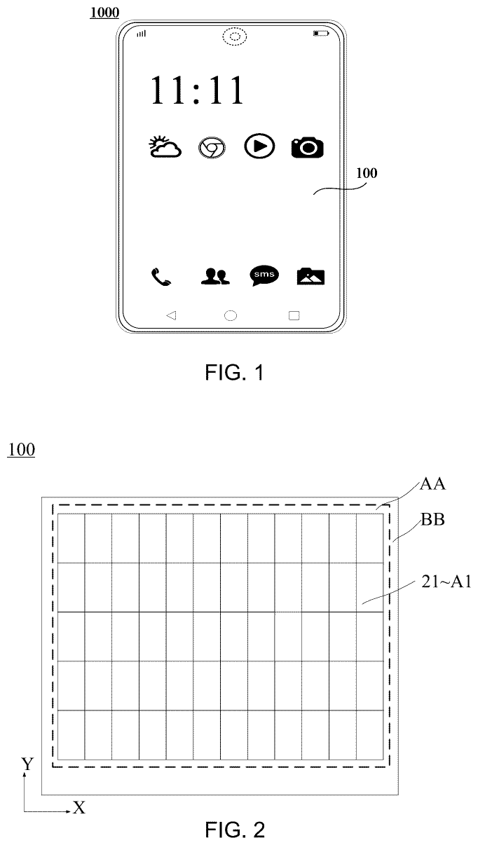

As shown in FIG. 1, some embodiments of the present disclosure provide a display device 1000. The display device provided in the embodiments of the present disclosure may be any device that displays images whether in motion (e.g., videos) or stationary (e.g., still images) and whether text or images. More specifically, it is expected that the embodiments may be implemented in or associated with a plurality of electronic devices. The plurality of electronic devices may include, but is not limit to, for example, mobile telephones, wireless devices, personal data assistants (PDAs), hand-held or portable computers, GPS receivers/navigators, cameras, MP4 video players, video cameras, game consoles, watches, clocks, calculators, TV monitors, flat panel displays, computer monitors, car displays (e.g., odometer displays), navigators, cockpit controllers and/or displays, camera view displays (e.g., rear view camera displays in vehicles), electronic photos, electronic billboards or indicators, projectors, building structures, or packagings and aesthetic structures (e.g., a display for an image of a piece of jewelry).

As shown in FIG. 1, in the embodiments of the present disclosure, the display device 1000 is used as a mobile phone for exemplary description.

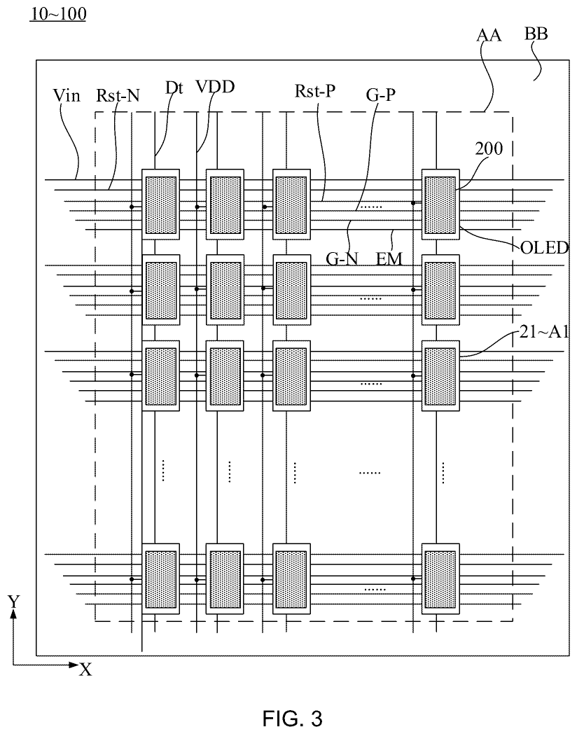

As shown in FIGS. 1 and 2, the display device 1000 includes a display panel 100. The display panel 100 includes a display area AA and a peripheral area BB located on at least one side of the display area AA. The display area AA is provided with a plurality of sub-pixels 21 and a plurality of signal lines therein. The plurality of sub-pixels 21 are arranged in the display area AA according to specified rules. A region where each sub-pixel 21 is located is a sub-pixel region A1. The sub-pixel 21 is the smallest unit for displaying images in the display panel 100, and each sub-pixel 21 may display a single color, such as red, green or blue. By adjusting the luminance of different sub-pixels 21, color superposition may be achieved to display multiple colors. As shown in FIG. 3, each sub-pixel 21 includes a light-emitting device OLED and a pixel driving circuit 200 for driving the light-emitting device OLED to emit light.

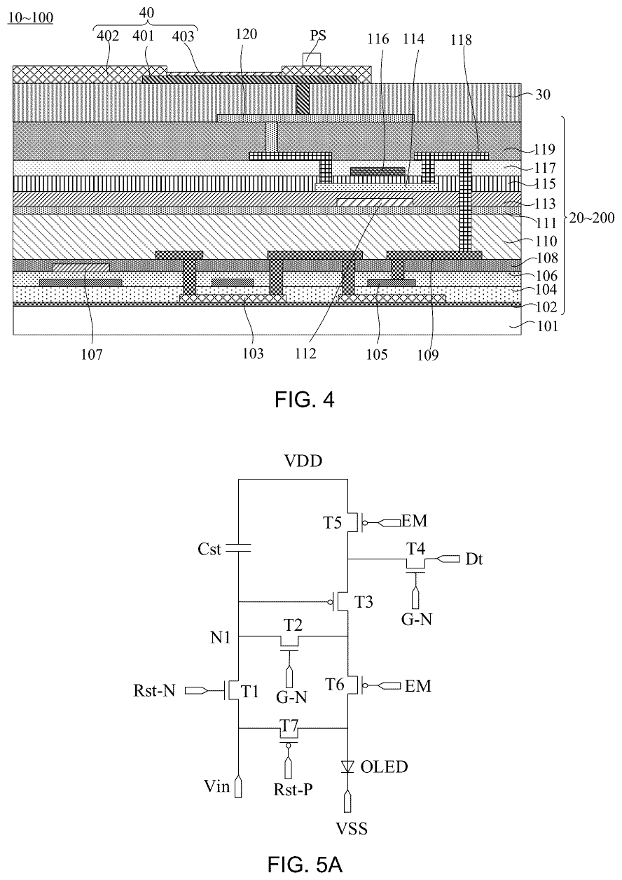

For example, considering an example in which the display panel 100 is an organic light-emitting diode (OLED) display panel, the display panel 100 includes an array substrate 10, a light-emitting device layer and an encapsulation layer that are arranged in sequence. The array substrate 10 is provided with a plurality of transistors and capacitor(s) included in the pixel driving circuits therein, and the light-emitting device layer includes a plurality of light-emitting devices OLED. As shown in FIG. 4, the array substrate 10 includes a base substrate 101 and a plurality of functional layers that are sequentially stacked on the base substrate 101, and insulating layers each located between adjacent functional layers; the functional layers may include active film layer(s), gate metal layer(s) and source-drain metal layer(s). The active film layer(s), the gate metal layer(s) and the source-drain metal layer(s) are used to form the plurality of pixel driving circuits 200 in the display panel 100. The plurality of pixel driving circuits 200 may be formed in the display area AA of the display panel 100, and the light-emitting devices OLED are disposed on a side of the pixel driving circuits 200 away from the base substrate 101.

The pixel driving circuit 200 includes a plurality of transistors, active layer patterns of the plurality of transistors are located in the active film layer(s), and the active layer pattern of each transistor includes a first electrode region, a second electrode region and a channel region for connecting the first electrode region and the second electrode region. Gates of the plurality of transistors are located in the gate metal layer(s); the gate metal layer(s) include, for example, a plurality of signal lines; a portion of a signal line passing through the active layer pattern of a certain transistor may be used as the gate of the transistor, and the term “passing through” here means that orthographic projections of the two on the base substrate overlap. During forming a transistor, an active film layer may be formed first on the base substrate 101 to obtain the active layer pattern of the transistor, and then a gate metal layer is formed on a side of the active film layer away from the substrate, and a position of the gate metal layer overlapping with the active film layer is the position of the gate metal layer “passing through” the active layer pattern. For example, the gate of a transistor overlaps with the channel region of the transistor.

The pixel driving circuit 200 is mainly composed of transistors. Therefore, the space occupied by the transistors may determine the space occupied by the pixel driving circuit 200. For example, the space occupied by the transistors includes a size of a transverse region parallel to a plane where the base substrate 101 is located and a size of a vertical region perpendicular to the plane where the base substrate 101 is located; the size of the vertical region is mainly related to a thickness of the film layers included in the array substrate 10. In the embodiments of the present disclosure, the sizes of the transverse regions of the transistors and the pixel driving circuit 200 parallel to the plane where the base substrate 101 is located are mainly considered. The size of the transverse region is an area of a region of orthographic projections of the transistors on the base substrate 101. Hereinafter, the area of the region of the orthographic projections of the transistors on the base substrate 101 is referred to as an area of the transistors, and the same is true for an area of the pixel driving circuit 200. The area of the active layer patterns of the transistors included in the pixel driving circuit 200 may affect the area of the pixel driving circuit 200.

The inventors of the present disclosure found that in the related arts, the pixel driving circuit 200 occupies a large area, resulting in a large space occupied by the sub-pixel 21, which is not conducive to achieving high pixels per inch (PPI) of the display panel. The active layer patterns of all the transistors in the pixel driving circuit 200 are arranged in parallel, and “arranged in parallel” means that the orthographic projections of any two transistors among all the transistors in the pixel driving circuit 200 on the base substrate 101 do not overlap. In this case, the area of the orthographic projection of the pixel driving circuit 200 on the base substrate 101 is a sum of the areas of the active layer patterns of the plurality of transistors in the pixel driving circuit 200, resulting in a great area of the orthographic projection of the pixel driving circuit 200 on the base substrate 101, so that the area occupied by the pixel driving circuit 200 is increased.

In light of this, some embodiments of the present disclosure provide an array substrate 10. The array substrate 10 includes a plurality of pixel driving circuits 200 and a plurality of signal lines. As shown in FIG. 3, the plurality of pixel driving circuits 200 are arranged in an array, and the plurality of signal lines include data signal lines Dt, gate lines, initialization signal lines Vin, and voltage signal lines; the gate lines and the initialization signal lines Vin extend in a first direction X, and the data signal lines Dt and power signal lines extend in the second direction Y. Each data signal line Dt is electrically connected to a column of pixel driving circuits 200, and at least one gate line is electrically connected to a row of pixel driving circuits 200. According to the functional division of at least one gate line electrically connected to a row of pixel driving circuits 200, the at least one gate line may include a scanning signal line, a reset signal line Rst, and a light-emitting control signal line EM.

As shown in FIG. 4, the array substrate 10 includes a base substrate 101 and two active film layers; the two active film layers include a first active film layer 103 and a second active film layer 114 that are sequentially arranged on the base substrate 101, and the two active film layer are insulated from each other. The plurality of transistors in the pixel driving circuit 200 are divided into a plurality of first-type transistors and a plurality of second-type transistors. The active layer patterns of the first-type transistors are located in the first active film layer 103, and the active layer patterns of the second-type transistors are located in the second active film layer 114; orthographic projections of the active layer patterns of the plurality of first-type transistors on the base substrate 101 at least partially overlap with orthographic projections of the active layer patterns of the plurality of second-type transistors on the base substrate 101. In this way, the active layers of the transistors in the pixel driving circuit 200 are arranged in different active film layers, and there is an overlapping portion between the layer patterns of the transistors in different active film layers, thereby reducing the total area of the orthographic projections of the plurality of transistors in the pixel driving circuit 200 on the base substrate 101 to reduce the area occupied by the pixel driving circuit 200. The solutions in the embodiments of the present disclosure will be introduced in detail below.

In some embodiments, the pixel driving circuit 200 in some embodiments of the present disclosure may be a circuit of 7T1C, 8T1C or 9T1C, where T represents a transistor, the number in front of T represents the number of transistors, and C represents a capacitor, and the number in front of C represents the number of capacitors. For example, 7T1C represents 7 transistors and 1 capacitor. The following will be described by considering the pixel driving circuit of 7T1C as an example.

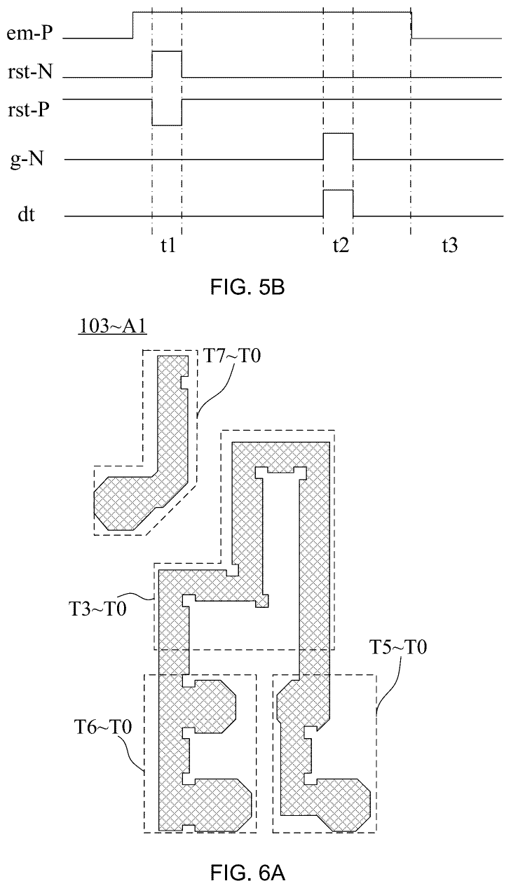

For example, as shown in FIGS. 5A and 5B, the pixel driving circuit 200 may specifically include a first reset transistor T1, a compensation transistor T2, a driving transistor T3, a writing transistor T4, a first light-emitting control transistor T5, a second light-emitting control transistor T6, a second reset transistor T7, and a capacitor Cst. The signal lines electrically connected to the pixel driving circuit 200 include a scanning signal line G-N, an initialization signal line Vin, a first reset signal line Rst-P, a second reset signal line Rst-N, and a light-emitting control signal line EM.

A gate of the first reset transistor T1 is electrically connected to the second reset signal line Rst-N, a first electrode region of the first reset transistor T1 is electrically connected to a first node N1, and a second electrode region of the first reset transistor T1 is electrically connected to the initialization signal line Vin; a gate of the compensation transistor T2 is electrically connected to the scanning signal line G-N, a first electrode region of the compensation transistor T2 is electrically connected to a second electrode region of the driving transistor T3, and a second electrode region of the compensation transistor T2 is electrically connected to the first node N1; a gate of the driving transistor T3 is electrically connected to the first node N1; a gate of the writing transistor T4 is electrically connected to the scanning signal line G-N, a first electrode region of the writing transistor T4 is electrically connected to the data signal line Dt, and a second electrode region of the writing transistor T4 is electrically connected to the first electrode region of the driving transistor T3; a gate of the first light-emitting control transistor T5 and a gate G6 of the second light-emitting control transistor T6 are both electrically connected to the light-emitting control signal line EM, a first electrode region of the first light-emitting control transistor T5 is electrically connected to a first voltage signal line VDD, and a second electrode region of the first light-emitting control transistor T5 is electrically connected to a first electrode region of the driving transistor T3; and a first electrode region of the second light-emitting control transistor T6 is electrically connected to the second electrode region of the driving transistor T3, and a second electrode region of the second light-emitting control transistor T6 is electrically connected to an anode of the light-emitting device OLED; a gate of the second reset transistor T7 is electrically connected to the first reset signal line Rst-P, a first electrode region of the second reset transistor T7 is electrically connected to the initialization signal line Vin, a second electrode region of the second reset transistor T7 is electrically connected to the anode of the light-emitting device OLED; the cathode of the light-emitting device OLED is electrically connected to a second voltage signal line VSS.

The scanning signal line G-N is used to transmit a scanning signal g-N, the first reset signal line Rst-P is used to transmit a first reset timing signal rst-P, the second reset signal line Rst-N is used to transmit a second reset timing signal rst-N, the first voltage signal line VDD is used to transmit a first voltage signal (e.g., a high-voltage direct current signal), the initialization signal line Vin is used to transmit an initialization signal, the data signal line Dt is used to transmit a data signal dt, the light-emitting control signal line EM is used to transmit a light-emitting control timing signal em, and the second voltage signal line VSS is used to transmit a second voltage signal (e.g., a low-voltage direct current signal).

As shown in FIG. 5B, the driving process of the pixel driving circuit 200 is as follows. A frame phrase includes a reset period t1, a data refresh and compensation period t2, and a light-emitting period t3. In the reset period t1, the first reset transistor T1 is turned on under control of the second reset timing signal rst-N, so that the initialization signal is written into the first node N1 to reset the first node N1; the second reset transistor T7 is turned on under control of the first reset timing signal rst-P, so that the initialization signal is written into the anode of the light-emitting device OLED to reset the anode of the light-emitting device OLED.

In this case, the driving transistor T3 is turned on, while the compensation transistor T2, the writing transistor T4, the first light-emitting control transistor T5 and the second light-emitting control transistor T6 are all in an off state, and the light-emitting device OLED does not emit light.

In the data refresh and compensation phase t2, the writing transistor T4 and the compensation transistor T2 are turned on under control of the scanning signal g-N, and the driving transistor T3 maintains to be in an on state in the reset period t1, so that the data signal dt may be transmitted to the first node N1 sequentially via the writing transistor T4, the driving transistor T3 and the compensation transistor T2, so that the voltage of the first node N1 changes, until the voltage of the first node N1 reaches a sum of a threshold voltage of the driving transistor T3 and a voltage of the data signal dt. Thus, the driving transistor T3 is turned off. In the data refresh and compensation period t2, the threshold voltage of the driving transistor T3 may be written into the first node N1 to compensate for the threshold voltage drift of the driving transistor T3, so as to avoid the changes in the driving signal generated by the driving transistor, thereby prevent from affecting the luminous intensity of the light-emitting device OLED. In this period, the first light-emitting control transistor T5 and the second light-emitting control transistor T6 are in an off state under the control of the light-emitting control timing signal em.

In the light-emitting period t3, the second reset transistor T7 is turned off under the control of the first reset timing signal rst-P, the first reset transistor T1 is turned off under the control of the second reset timing signal rst-N, the writing transistor T4 and the compensation transistor T2 are turned off under the control of the scanning signal g-N, and the first light-emitting control transistor T5 and the second light-emitting control transistor T6 are turned on under the control of the light-emitting control timing signal em, so that the voltage signal of the first voltage signal line VDD is written into the first electrode region of the driving transistor T3. Thus, the driving transistor T3 is turned on, so that a path is created between the first voltage signal line VDD and the light-emitting device OLED to enable the light-emitting device OLED to emit light.

It will be noted that, in the embodiments of the present disclosure, the first electrode region of the transistor is one of a source and a drain of the transistor, and the second electrode region of the transistor is the other of the source and the drain of the transistor. Since the source and the drain of the transistor may be symmetrical in structure, the source and the drain thereof may be indistinguishable in structure. That is, the first electrode region and the second electrode region of the transistor in the embodiments of the present disclosure may be indistinguishable in structure. For example, in a case where the transistor is a P-type transistor, the first electrode region of the transistor is the source, and the second electrode region of the transistor is the drain. For another example, in a case where the transistor is an N-type transistor, the first electrode region of the transistor is the drain, and the second electrode region of the transistor is the source.

In the circuits provided in the embodiments of the present disclosure, nodes do not represent actual components, but represent junctions of relevant electrical connections in a circuit diagram. That is, these nodes are nodes equivalent to junctions of relevant electrical connections in the circuit diagram.

The pixel driving circuit 200 uses an low temperature polycrystalline oxide (LTPO) circuit; that is, the pixel driving circuit 200 includes both a low temperature polysilicon (LTPS) thin film transistor and an oxide thin film transistor; the low temperature polysilicon thin film transistor has strong load capacity, and the oxide thin film transistor has a small off-state current and has a stronger charge retention capabilities than the low temperature polysilicon thin film transistor. In this way, the pixel driving circuit 200 may achieve a high charge mobility and good stability.

In some examples, the oxide transistor is an N-type transistor, and the LTPS transistor is a P-type transistor; the N-type transistor is turned on in a case where a high voltage signal is received at the gate, and the P-type transistor is turned on in a case where a low voltage signal is received at the gate. For example, as shown in FIG. 5A, the first reset transistor T1, the compensation transistor T2 and the writing transistor T4 are all oxide thin film transistors and N-type transistors, i.e., being turned on at a high level. The driving transistor T3, the first light-emitting control transistor T5, the second light-emitting control transistor T6 and the second reset transistor T7 are all LTPS transistors and P-type transistors, i.e., being turned on at a low level. The first reset transistor T1 and the compensation transistor T2 are configured as oxide thin film transistors, which may effectively prevent the current leakage of the first node N1.

It will be noted that the “high voltage signal” and “low voltage signal” mentioned above are common terms. Generally speaking, the conduction condition of the N-type transistor is that a gate-source voltage difference is greater than a threshold voltage thereof, i.e., a gate voltage of the N-type transistor is greater than a sum of a source voltage thereof and the threshold voltage thereof, the threshold voltage of the N-type transistor is positive, then a gate voltage signal that turns on the N-type transistor is referred to as a high-voltage signal; the conduction condition of the P-type transistor is that an absolute value of a gate-source voltage difference is greater than a threshold voltage thereof, and the threshold voltage of the P-type transistor is negative, i.e., a gate voltage of the P-type transistor is less than a sum of a source voltage thereof and the threshold voltage thereof, then a gate voltage signal that turns on the P-type transistor is referred to as a low voltage signal. “High” in the “high voltage signal” and “low” in the “low voltage signal” are relative to the reference voltage (e.g., 0 V).

The structure of each film layer included in the array substrate 10 and the arrangement of each transistor in the pixel driving circuit will be described below.

For example, as shown in FIG. 4, the array substrate 10 includes a base substrate 101 and a pixel circuit stack layer 20, and the pixel circuit stack layer 20 is disposed on the base substrate 101.

For example, a material of the base substrate 101 may include any one of glass, metal, or a flexible material.

A plurality of pixel driving circuits 200 are formed in the pixel circuit stack layer 20. For example, the pixel circuit stack layer 20 includes a first buffer layer 102, a first active film layer 103, a first gate insulating layer 104, a first gate metal layer 105, a second gate insulating layer 106, a second gate metal layer 107, a first interlayer dielectric layer 108, a first source-drain metal layer 109, a first planarization layer 110, a second buffer layer 111, a third gate metal layer 112, a third gate insulating layer 113, a second active film layer 114, a fourth gate insulating layer 115, a fourth gate metal layer 116, a second interlayer dielectric layer 117, a second source-drain metal layer 118, a second planarization layer 119 and a third source-drain metal layer 120 that are sequentially stacked.

For example, the first buffer layer 102 and the second buffer layer 111 are formed by means of plasma enhanced chemical vapor deposition (PECVD), and the materials of them may be silicon nitride, silicon oxide or silicon oxynitride, which have the function of blocking moisture and oxygen. A thickness of silicon nitride may be in a range of 30 nm to 70 nm, inclusive, and a thickness of silicon oxide may be in a range of 250 nm to 350 nm, inclusive.

For example, the first active film layer 103 is formed by using an excimer laser annealing process, and is made of low temperature polysilicon, and a thickness is in a range of 30 nm to 50 nm, inclusive; the second active film layer 114 is formed by using a physical vapor deposition (PVD) process, a thickness is in a range of 30 nm to 50 nm, inclusive, and the material may be any one of indium gallium zinc oxide or low temperature polycrystalline oxide, such as indium gallium zinc oxide (IGZO) or indium gallium zinc tin oxide (IGZTO).

For example, the first gate insulating layer 104, the second gate insulating layer 106, the third gate insulating layer 113 and the fourth gate insulating layer 115 are made of silicon nitride, silicon oxide or silicon oxynitride by using a PECVD process, and the thicknesses are each in a range of 100 nm to 150 nm.

For example, the first gate metal layer 105, the second gate metal layer 107, the first source-drain metal layer 109, the third gate metal layer 112, the fourth gate metal layer 116, the second source-drain metal layer 118 and the third source-drain metal layer 120 are formed mainly by depositing metal materials such as molybdenum/titanium/aluminum/copper (MO/Ti/Al/Cu) by using a PVD process, and the thicknesses are each in a range of 300 nm to 800 nm, inclusive.

For example, the first interlayer dielectric layer 108 and the second interlayer dielectric layer 117 may be made of any one of silicon nitride, silicon oxide, or silicon oxynitride, or a combination of any two of them, and are formed by using a PECVD process, and the thicknesses are each in a range of 400 nm to 800 nm, inclusive.

For example, the first planarization layer 110 is coated with polyimide (PI) by using a spin coating process, and a thickness is in a range of 1.5 μm to 2 μm, inclusive; the second planarization layer 119 may be coated with PI by using a spin coating process, or may be formed by depositing silicon nitride, silicon oxide or silicon oxynitride by using the PECVD process, which is mainly used to block moisture and oxygen and block alkaline ions; a thickness is in a range of 400 nm to 800 nm, inclusive.

In some embodiments, the material of the first planarization layer 110 may be PI. In this case, the thickness of the first planarization layer 110 is greater than the thickness of the second planarization layer 119. The first planarization layer 110 has a greater thickness, which may prevent signal crosstalk occurs between the two active film layers.

In some other embodiments, the material of the first planarization layer 110 may be inorganic insulating materials such as silicon oxide or silicon nitride. In a case where the first planarization layer 110 is made of an inorganic material, the thickness of the film layer is small (less than 1.5 microns), which reduces a size of via holes in the first planarization layer 110 to further improve the PPI.

For example, in a case where the material of the first planarization layer 110 is an inorganic insulating material, a surface of the first planarization layer 110 proximate to the second planarization layer 119 may be made flat by means of chemical mechanical polishing (CMP).

As shown in FIGS. 2, 3, 4, 6A and 6G, the array substrate 10 includes a plurality of sub-pixel regions A1, and each sub-pixel region A1 is provided with a pixel driving circuit 200 therein; a plurality of pixel driving circuits 200 are arranged in multiple rows and columns; each pixel driving circuit 200 of the plurality of pixel driving circuits 200 includes a plurality of first-type transistors T0 and a plurality of second-type transistors T0′, and the plurality of second-type transistors T0′ include at least a writing transistor T4. The array substrate 10 includes a base substrate 101, a first active film layer 103 disposed on a side of the base substrate 101, a second active film layer 114 disposed on a side of the first active film layer 103 away from the base substrate 101, and a third source-drain metal layer 120 disposed on a side of the second active film layer 114 away from the base substrate 101. The first active film layer 103 includes active layer patterns of the plurality of first-type transistors TO, and the second active film layer 114 includes active layer patterns of the plurality of second-type transistors T0′, such as an active layer pattern of the writing transistor T4. The third source-drain metal layer 120 includes data signal lines Dt. The active layer pattern of the writing transistor T4 is electrically connected to the data signal line Dt.

It will be noted that the active layer pattern of the writing transistor T4 is disposed in the second active film layer 114, and the data signal lines Dt are disposed in the third source-drain metal layer 120 on a side away from the transistor. Thus, compared with arranging the data signal lines Dt in the first source-drain metal layer 109 or the second source-drain metal layer 118, in this solution, it may be possible to avoid crosstalk caused by the parasitic capacitance generated between the data signal line Dt and the metal transfer pattern in the first source-drain metal layer 109 or the second source-drain metal layer 118; moreover, the data signal lines are arranged in the third source-drain metal layer, so that the wiring space is increased, the spacing between adjacent data signal lines is increased, and the interference phenomenon generated between the signal lines is ameliorated. Furthermore, the data signal lines Dt may directly transmit the signals to the second source-drain metal layer 118 through the via holes penetrating through the second planarization layer 119, which facilitates the provision of the data signal for the first electrode region of the writing transistor T4. If the active layer pattern of the writing transistor T4 is disposed in the first active film layer 103, the data signal lines Dt located in the third source-drain metal layer 120 need to penetrate through at least two via holes in multiple film layers, i.e., the via holes in the first planarization layer 110 and the second planarization layer 119. The number of via holes will affect the improvement of the PPI of the display panel, and the greater the number of via holes, the more likely it is that defective via holes may affect the yield of the display panel. Therefore, compared with the related arts, on the basis of achieving a reasonable layout of data signal lines, reducing parasitic capacitance, and improving signal transmission stability, the above settings may not only simplify the manufacturing process, but also improve the PPI of the display panel, thereby improving the display effect of the display panel to improve yield.

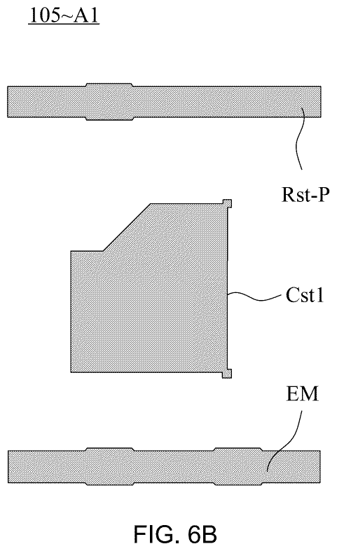

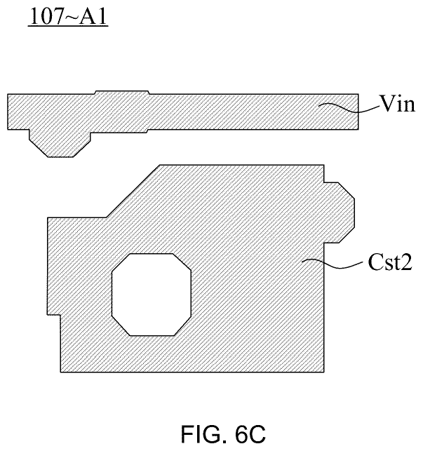

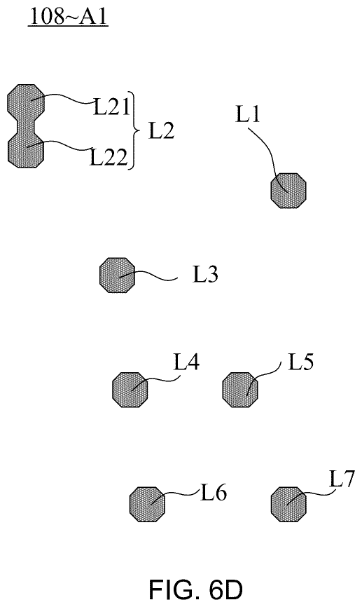

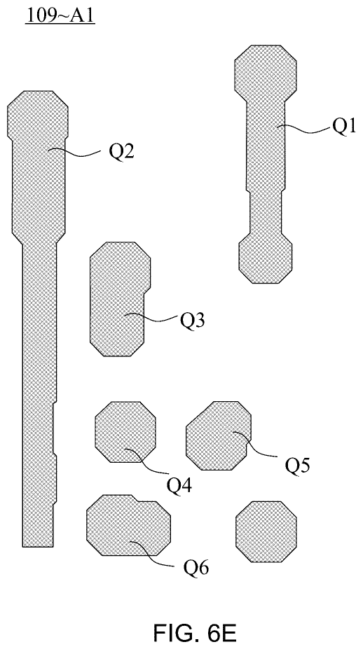

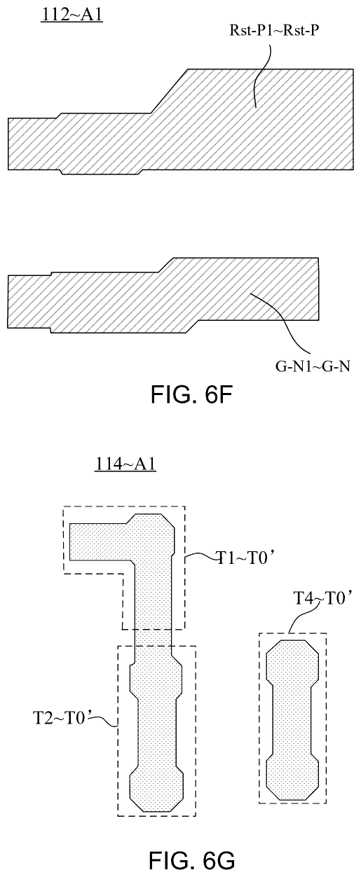

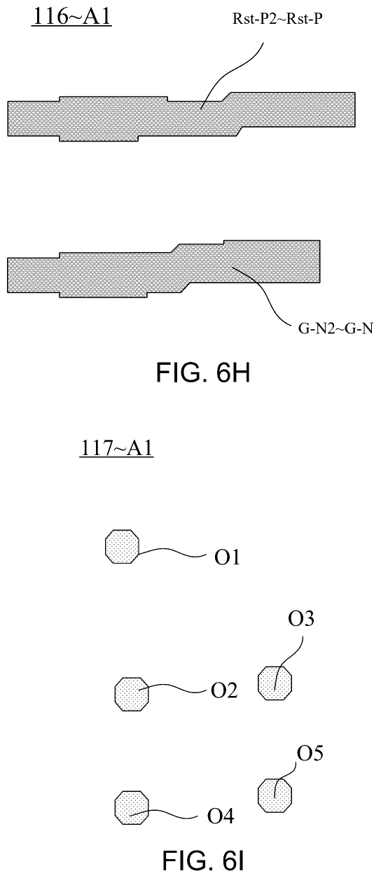

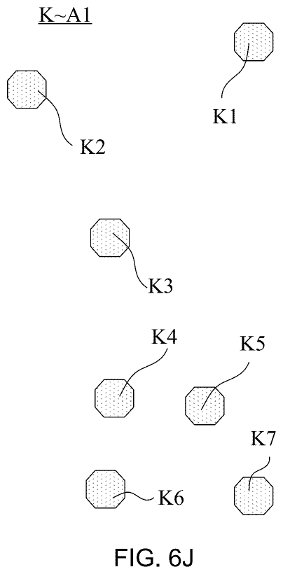

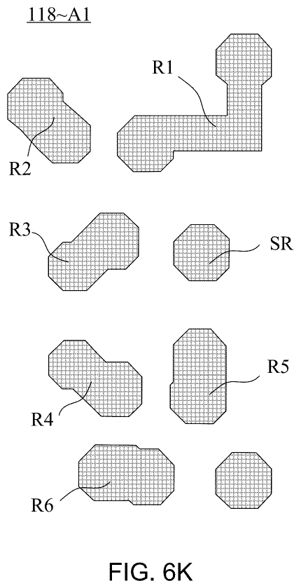

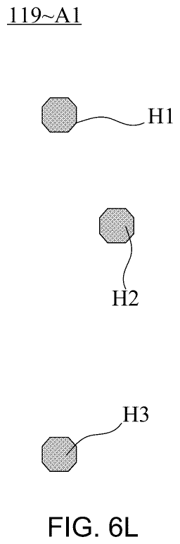

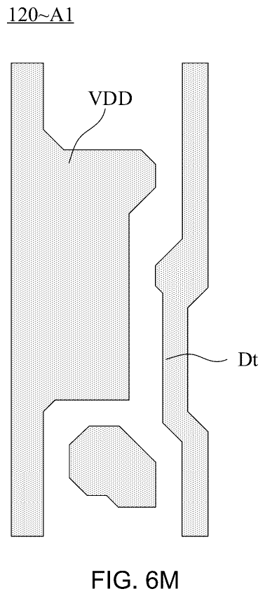

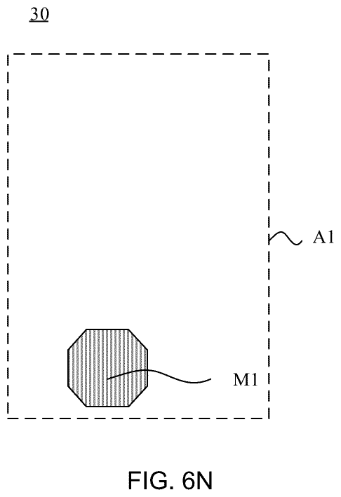

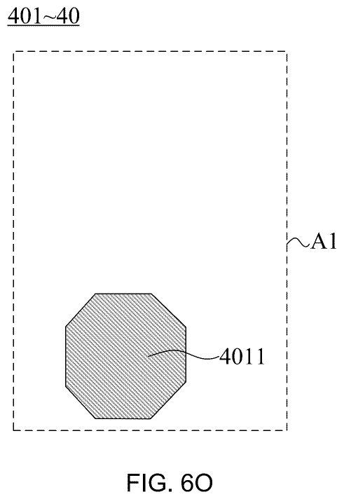

In some embodiments, as shown in FIGS. 4, 6E and 6K, the array substrate 10 further includes a first source-drain metal layer 109 disposed between the first active film layer 103 and the second active film layer 114 and a second source-drain metal layer 118 between the active film layer 114 and the third source-drain metal layer 120. In the sub-pixel region A1, the second source-drain metal layer 118 includes a data line transfer pattern SR; the data signal line Dt is connected to the data line transfer pattern SR through a via hole, and the data line transfer pattern SR is connected to the active layer pattern of the writing transistor T4.

It will be understood that, with reference to FIGS. 4, 6L, 6K and 6M, according to the above description, the second planarization layer 119 is disposed between the second source-drain metal layer 118 and the third source-drain metal layer 120. The second planarization layer 119 is provided with a plurality of first-type via holes H therein, and the plurality of first-type via holes H include a first-type via hole H1, a first-type via hole H2, and a first-type via hole H3. The data signal line Dt is connected to the data line transfer pattern SR located in the second source-drain metal layer 118 through the first-type via hole H2 penetrating through the second planarization layer 119. An interlayer dielectric layer 117 is disposed between the second source-drain metal layer 118 and the second active film layer 114, referring to FIGS. 4, 61, 6K, 6G and 6M, the second interlayer dielectric layer 117 is provided with a plurality of second-type via holes O, and the plurality of second-type via holes O include a second-type via hole O1, a second-type via hole O2, a second-type via hole O3, a second-type via hole O4 and a second-type via hole O5, the data line transfer pattern SR is connected to the active layer pattern of the writing transistor T4 in the second active film layer 114 through the second-type via hole O3 penetrating through the second interlayer dielectric layer 117 and a via hole penetrating through the fourth gate insulating layer 115, so as to ensure that the writing transistor T4 receives the data signal transmitted by the data signal line Dt.

The data line transfer pattern SR is disposed in the second source-drain metal layer 118, and the data line transfer pattern SR serves to connect the third source-drain metal layer and the second active film layer, so that the data signal line is connected to the writing transistor to realize the transmission of data signal.

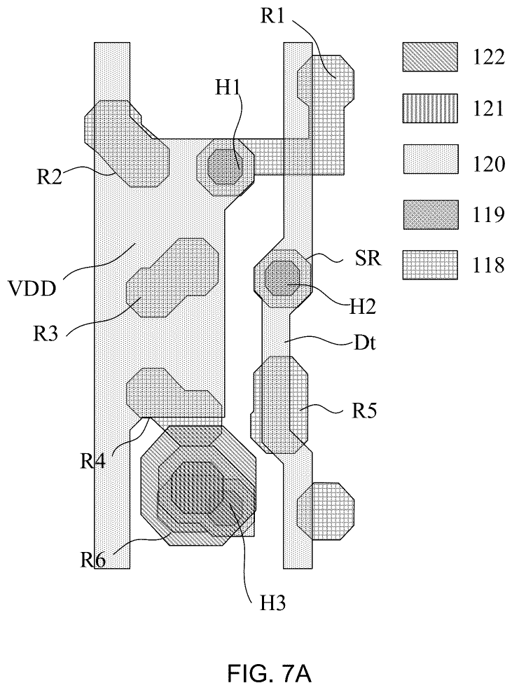

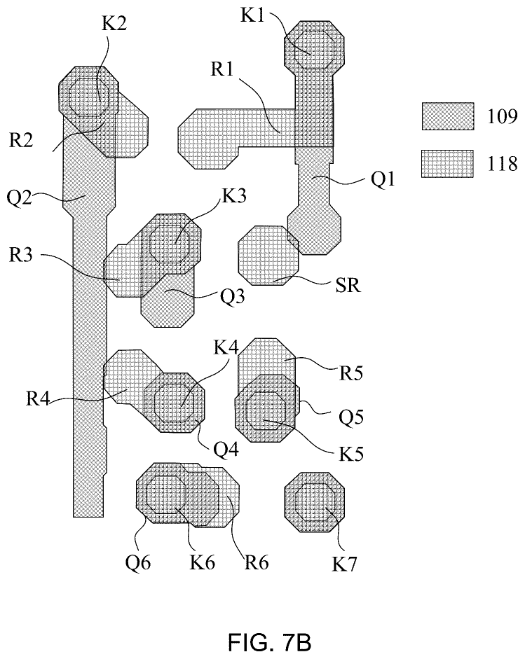

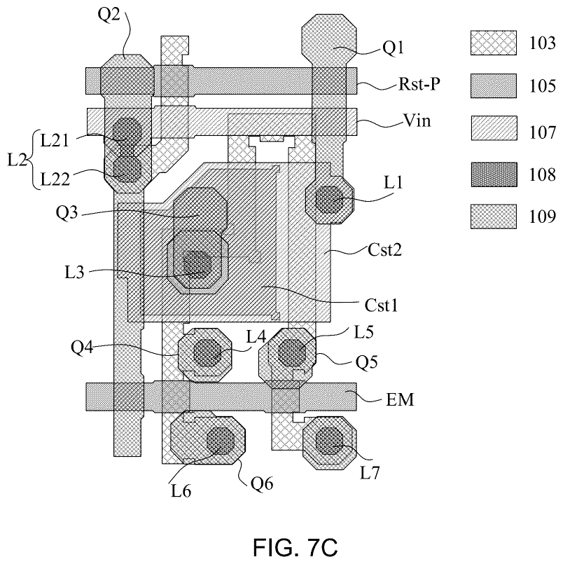

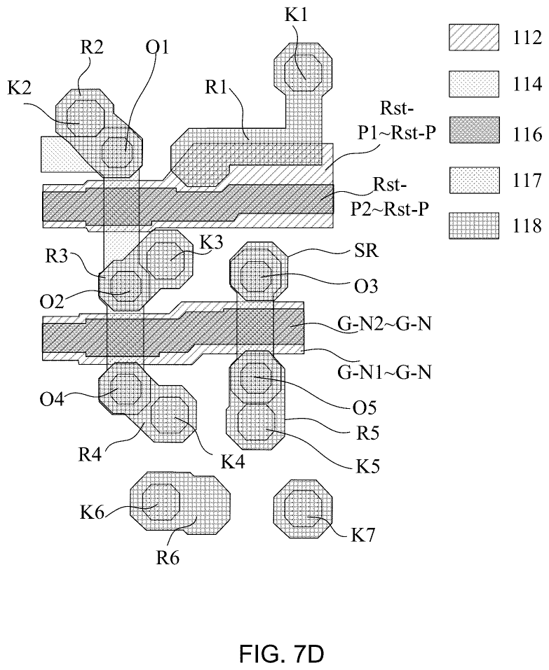

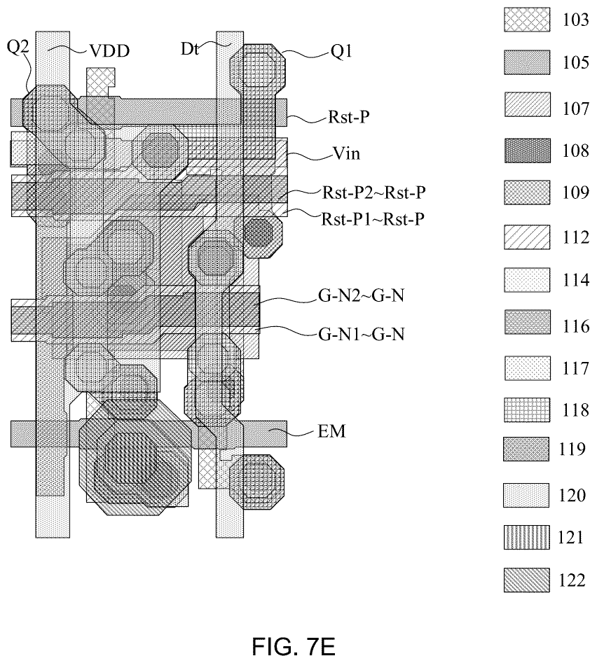

In some embodiments, referring to FIG. 4, FIGS. 6A to 6M and FIG. 7E, the pixel driving circuit 200 further includes a capacitor Cst; the array substrate 10 further includes a first gate metal layer 105 and a second gate metal layer 107 that are sequentially arranged on the side of the first active film layer 103 away from the base substrate 101. In the sub-pixel region A1, the first gate metal layer 105 includes a first plate pattern Cst1 of the capacitor Cst, and the second gate metal layer 107 includes a second plate pattern Cst2 of the capacitor Cst; the third source-drain metal layer 120 further includes the first voltage signal line VDD; in the sub-pixel region A1, the second source-drain metal layer 118 further includes a first transfer pattern R1, and the first source-drain metal layer 109 includes a first bridging pattern Q1. The first voltage signal line VDD is connected to the first transfer pattern R1 in the second source-drain metal layer 118 through a via hole, and the first transfer pattern R1 is connected to the first bridging pattern Q1 in the first source-drain metal layer 109 through a via hole. The first bridging pattern Q1 is connected to the second plate pattern Cst2 in the second gate metal layer 107 through a via hole, so that the first voltage signal line VDD is electrically connected to the second plate pattern Cst2.

For example, referring to FIGS. 6E, 6K and 6M, FIG. 6E being a diagram showing a film structure of the first source-drain metal layer 109, FIG. 6K being a diagram showing a film structure of the second source-drain metal layer 118, FIG. 6M being a diagram showing a film structure of the third source-drain metal layer 120, the first source-drain metal layer 109 includes the first bridging pattern Q1, the second source-drain metal layer 118 includes the first transfer pattern R1, and the third source-drain metal layer 120 includes the first voltage signal line VDD. Referring to FIG. 7A, FIG. 7A being a diagram showing a connection structure between the second source-drain metal layer 118 and the third source-drain metal layer 120, the first voltage signal line VDD is connected to the first transfer pattern R1 in the second source-drain metal layer 118 through the first-type via hole H1 penetrating through the second planarization layer. Referring to FIGS. 7B and 6J, FIG. 7B being a diagram showing a connection structure between the second source-drain metal layer 118 and the first source-drain metal layer 109, an insulating layer is provided between the second source-drain metal layer 118 and the first source-drain metal layer 109, the insulating layer may include the first planarization layer 110, the second buffer layer 111, the third gate insulating layer 113, the fourth gate insulating layer 115 and the second interlayer dielectric layer 117; the insulating layer is provided with third-type via holes K therein, and the third-type via holes K include a third-type via hole K1, a third-type via hole K2, a third-type via hole K3, a third-type via hole K4, a third-type via hole K5, a third-type via hole K6 and a third-type via hole K7; the first transfer pattern R1 is connected to the first bridging pattern Q1 in the first source-drain metal layer 109 through the third-type via hole K1 penetrating through the insulating layer. Referring to FIGS. 7C and 6D, the first interlayer dielectric layer 108 is disposed between the first source-drain metal layer 109 and the second gate metal layers 107, the first interlayer dielectric layer 108 is provided with fourth-type via holes L, which includes a fourth-type via hole L1, a fourth-type via hole L2, a fourth-type via hole L3, a fourth-type via hole L4, a fourth-type via hole L5, a fourth-type via hole L6, and a fourth-type via hole L7; the first bridging pattern Q1 is connected to the second plate pattern Cst2 in the second gate metal layer 107 through the fourth-type via hole L1, so that the second plate pattern Cst2 of the capacitor receives the first voltage signal transmitted by the first voltage signal line VDD.

The above arrangement that the first voltage signal lines VDD are disposed in the third source-drain metal layer 120 is mainly to increase the wiring space and reduce the resistance of the first voltage signal lines VDD to a certain extent; moreover, it is possible to prevent the signal interference caused by other signal lines on the first voltage signal line VDD, improve the signal transmission efficiency of the first voltage signal line VDD to further realize the electrical connection to the capacitor.

In some embodiments, referring to FIGS. 4, 6A and 6G, the second-type transistors T0′ further include a first reset transistor T1 and a compensation transistor T2, and the first-type transistors T0 include a driving transistor T3, a first light-emitting control transistor T5, a second light-emitting control transistor T6 and a second reset transistor T7; the first active film layer 103 includes an active layer pattern of the driving transistor T3, an active layer pattern of the first light-emitting control transistor T5, an active layer pattern of the second light-emitting control transistor T6, and an active layer pattern of the second reset transistor T7; the second active film layer 114 further includes an active layer pattern of the first reset transistor T1 and an active layer pattern of the compensation transistor T2.

It will be understood that the active layer patterns of the above first-type transistors T0 and the active layer patterns of the second-type transistors T0′ are respectively located in different active film layers, compared with the related arts in which the active layer patterns of the transistors are all disposed in the same active film layer, it is possible to reduce the size of the transverse region parallel to the plane where the base substrate is located, i.e., reduce the area occupied by the orthographic projections of the first-type transistors T0 and the second-type transistors T0′ on the base substrate, thereby reducing the area occupied by the orthographic projection of the pixel driving circuit 200 on the base substrate to improve the space utilization.

For example, the second-type transistors T0′ are all oxide thin film transistors and are all N-type transistors, and the first-type transistors T0 are all low temperature polysilicon thin film transistors and are all P-type transistors. The first planarization layer 110 is disposed between the first active film layer 103 the second active film layers 114. Thus, it is possible to ensure the flat bottom of the second-type transistors T0′, and play a certain isolation role between the first-type transistors T0 and the second-type transistors T0′, which may reduce the parasitic capacitance between the first-type transistors T0 and the second-type transistors T0′, so as to avoid signal interference between them.

In some embodiments, referring to FIGS. 4, 6E, 6F, 6G, 6H, and 7D, the array substrate 10 further includes: a third gate metal layer 112 between the first source-drain metal layer 109 and the second active film layer 114, and a fourth gate metal layer 116 disposed on a side of the second active film layer 114 away from the third gate metal layer 112. The third gate metal layer 112 includes a first reset signal line first branch line Rst-P1 and a scanning signal line first branch line G-N1; the first reset signal line first branch line Rst-P1 passes through the active layer pattern of the first reset transistor T1, and the scanning signal line first branch line G-N1 passes through both the active layer pattern of the compensation transistor T2 and the active layer pattern of the writing transistor T4. The fourth gate metal layer 116 includes a first reset signal line second branch line Rst-P2 and a scanning signal line second branch line G-N2; the first reset signal line second branch line Rst-P2 passes through the active layer pattern of the first reset transistor T1, and the scanning signal line second branch line G-N2 passes through both the active layer pattern of the compensation transistor T2 and the active layer pattern of the writing transistor T4. The first reset line first branch line Rst-P1 is electrically connected to the first reset signal line second branch line Rst-P2, and the scanning signal line first branch line G-N1 is electrically connected to the scanning signal line second branch line G-N2.

For example, referring to FIG. 7D, it can be seen from the above arrangement that, portions of the scanning signal line first branch line G-N1 passing through the active layer pattern of the compensation transistor T2 and the active layer pattern of the writing transistor T4 respectively serves as the gate of the compensation transistor T2 and the gate of the writing transistor T4. That is, the gate of the compensation transistor T2 and the gate of the writing transistor T4 receive the same signal; and it can be seen, from the description of the scanning signal line first branch line G-N1 being electrically connected to the scanning signal line second branch line G-N2, that the gate of the compensation transistor T2 and the gate of the writing transistor T4 both receive the same scanning signal g-N. Therefore, the compensation transistor T2 and the writing transistor T4 may share a scanning signal line, compared with the related art in which the compensation transistor T2 and the write transistor T4 are arranged in different layers, and the two transistors are of different types and cannot share a gate signal, it is possible to reduce the number of scanning signal lines, and greatly save the space of the pixel driving circuit to a certain extent.

By arranging the scanning signal line first branch line G-N1, the scanning signal line second branch line G-N2, the first reset signal line first branch line Rst-P1 and the first reset signal line second branch line Rst-P2, the reasonable wiring is achieved to a certain extent to avoid crosstalk between signal lines caused by the insufficient wiring space. Furthermore, by providing two branch lines and applying a scanning signal to the upper and lower sides of the active layer patterns of the compensation transistor T2 and the write transistor T4, it is possible to enhance the intensity of the scan signal received by the transistors and enhance the conduction degree of the channel regions of the active layer patterns of the compensation transistor T2 and the writing transistor T4, so that the on and off of the compensation transistor T2 and the write transistor T4 may be well controlled.

In some embodiments, referring to FIGS. 4, 6A, 6C, 6E, 6G, 6K, 7C and 7D, the array substrate 10 further includes the second gate metal layer 107, the first source-drain metal layer 109 and the second source-drain metal layer 118. The second gate metal layer 107 further includes a plurality of initialization signal lines Vin. In the sub-pixel region A1, the first source-drain metal layer 109 further includes a second bridging pattern Q2, and the second source-drain metal layer 118 further includes a second transfer pattern R2. The second bridging pattern Q2 is electrically connected to the active layer pattern of the second reset transistor T7 and the initialization signal line Vin through two via holes, so that the active layer pattern of the second reset transistor T7 is electrically connected to the initialization signal line Vin. The second transfer pattern R2 is connected to the second bridging pattern Q2 and the active layer pattern of the first reset transistor T1 through two via holes, so that the active layer pattern of the first reset transistor T1 is electrically connected to the initialization signal line Vin.

It will be noted that, referring to FIG. 7C, the second bridging pattern Q2 is electrically connected to the initialization signal line Vin through the fourth-type via hole L21 penetrating through the first interlayer dielectric layer 108, and is electrically connected to the active layer pattern of the second reset transistor T7 through the fourth-type via hole L22 penetrating through the first interlayer dielectric layer 108. The fourth-type via hole L21 and the fourth-type via hole L22 are communicated to each other, so that the second reset transistor T7 may receive initialization signal from the initialization signal line Vin. Referring to FIG. 7D, the second transfer pattern R2 is connected to the second bridging pattern Q2 through the third-type via hole K2, and is connected to the active layer pattern of the first reset transistor T1 in the second active film layer 114 through the second-type via hole O1 penetrating through the second interlayer dielectric layer 117, so that the first reset transistor T1 may receive the initialization signal of the initialization signal line Vin.

In some embodiments, referring to FIGS. 6E and 6K, and FIGS. 7B to 7D, in the sub-pixel region A1, the first source-drain metal layer 109 further includes a third bridging pattern Q3, and the second source-drain metal layer 118 further includes a third transfer pattern R3. The third bridging pattern Q3 is connected to the first plate pattern Cst1 of the capacitor Cst in the first gate metal layer 105 through a via hole, the third transfer pattern R3 is connected to the third bridging pattern Q3 through a via hole, and the active layer pattern of the compensation transistor T2 in the second active film layer 114 is connected to the third transfer pattern R3 through a via hole, so that the compensation transistor T2 is electrically connected to the first plate pattern.

For example, referring to FIGS. 6E and 7C, the third bridging pattern Q3 is connected to the first plate pattern Cst1 of the capacitor Cst in the first gate metal layer 105 through the fourth-type via hole L3 penetrating the first interlayer dielectric layer 108. Referring to FIG. 7B, the third transfer pattern R3 is connected to the third bridging pattern Q3 through the third-type via hole K3. Referring again to FIG. 7D, the active layer pattern of the compensation transistor T2 in the second active film layer 114 is connected to the third transfer pattern R3 through the second-type via hole O2 passing through the second interlayer dielectric layer 117. With such the connection manner, it is possible to achieve that the compensation transistor T2 is electrically connected to the first plate pattern of the capacitor Cst.

In some embodiments, referring to FIGS. 6E and 6K, and FIGS. 7B to 7D, in the sub-pixel region A1, the first source-drain metal layer 109 further includes a fourth bridging pattern Q4, and the second source-drain metal layer 118 further includes a fourth transfer pattern R4. The fourth bridging pattern Q4 is connected to the active layer pattern of the second light-emitting control transistor T6 in the first active film layer 103 through a via hole; the fourth transfer pattern R4 is connected to the fourth bridging pattern Q4 through a via hole, and the active layer pattern of the compensation transistor T2 in the second active film layer 114 is connected to the fourth transfer pattern R4 through a via hole, so that the compensation transistor T2 is electrically connected to the second light-emitting control transistor T6.

For example, referring to FIGS. 6E and 7C, the fourth bridging pattern Q4 is connected to the active layer pattern of the second light-emitting control transistor T6 in the first active film layer 103 through the fourth-type via hole L4 penetrating through the first interlayer dielectric layer 108. Referring to FIG. 7B, the fourth transfer pattern R4 is connected to the fourth bridging pattern Q4 through the third-type through hole K4. Referring to FIG. 7D, the active layer pattern of the compensation transistor T2 in the second active film layer 114 is connected to the fourth transfer pattern R4 through the second-type via hole O4 penetrating through the second interlayer dielectric layer 117. With such the connection manner, the compensation transistor T2 is electrically connected to the second light-emitting control transistor T6.

In some embodiments, referring to FIG. 6E, and 6K, and FIGS. 7B to 7D, in the sub-pixel region A1, the first source-drain metal layer 109 further includes a fifth bridging pattern Q5, and the second source-drain metal layer 118 further includes a fifth transfer pattern R5. The fifth bridging pattern Q5 is connected to the active layer pattern of the first light-emitting control transistor T5 in the first active film layer 103 through a via hole, and the fifth transfer pattern R5 is connected to the fifth bridging pattern Q5 through a via hole, and the active layer pattern of the writing transistor T4 in the second active film layer 114 is connected to the fifth transfer pattern R5 through a via hole, so that the writing transistor T4 is electrically connected to the first light-emitting control transistor T5.

For example, referring to FIGS. 6E and 7C, the fifth bridging pattern Q5 is connected to the active layer pattern of the first light-emitting control transistor T5 in the first active film layer 103 through the fourth-type via hole L5 penetrating through the first interlayer dielectric layer 108. Referring to FIG. 7B, the fifth transfer pattern R5 is connected to the fifth bridging pattern Q5 through the third-type via hole K5. Referring to FIG. 7D, the active layer pattern of the writing transistor T4 in the second active film layer 114 is connected to the fifth transfer pattern R5 through the second-type via hole O5 penetrating through the second interlayer dielectric layer 117. With such the connection manner, the writing transistor T4 is electrically connected to the first light-emitting control transistor T5.

In some embodiments, referring to FIGS. 6E, 6K, 7B and 7C, in the sub-pixel region A1, the first source-drain metal layer 109 further includes a sixth bridging pattern Q6, and the second source-drain metal layer 118 further includes a sixth transfer pattern R6; the sixth bridging pattern Q6 is connected to the active layer pattern of the second light-emitting control transistor T6 in the first active film layer 103 through a via hole; the sixth transfer pattern R6 is connected to the sixth bridging pattern Q6.

For example, referring to FIGS. 6E and 7C, the sixth bridging pattern Q6 is connected to the active layer pattern of the second light-emitting control transistor T6 in the first active film layer 103 through the fourth-type via hole L6 penetrating through the first interlayer dielectric layer 108. Referring to FIG. 7B, the sixth transfer pattern R6 is connected to the sixth bridging pattern Q6 through the third-type through hole K6.

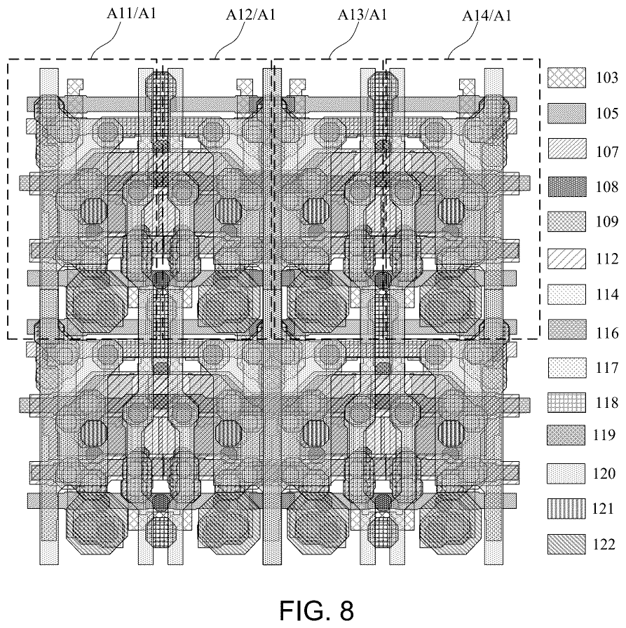

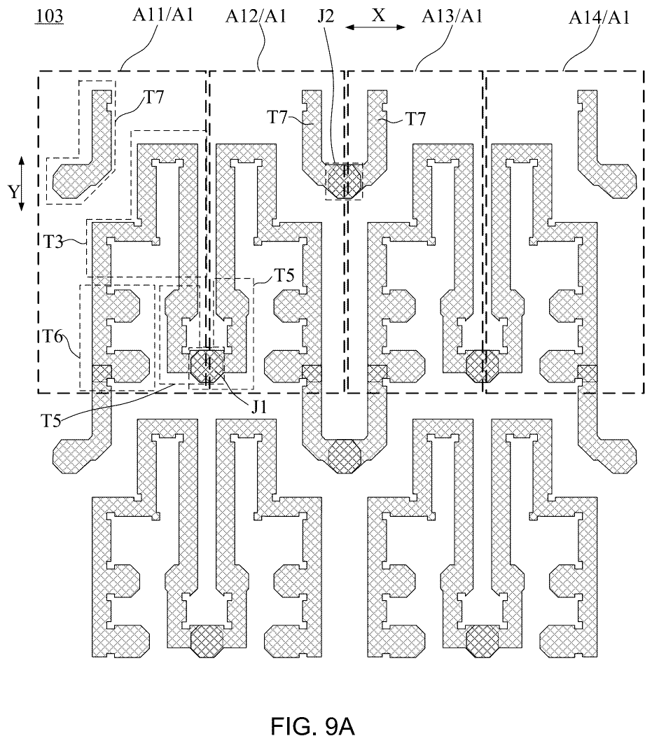

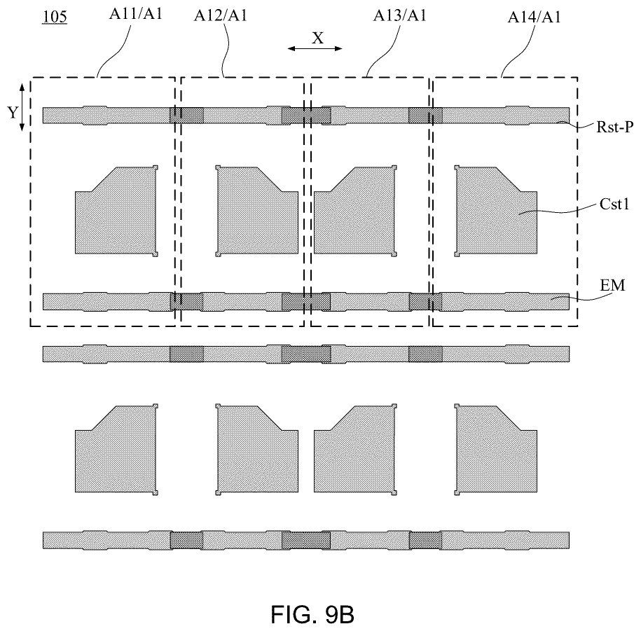

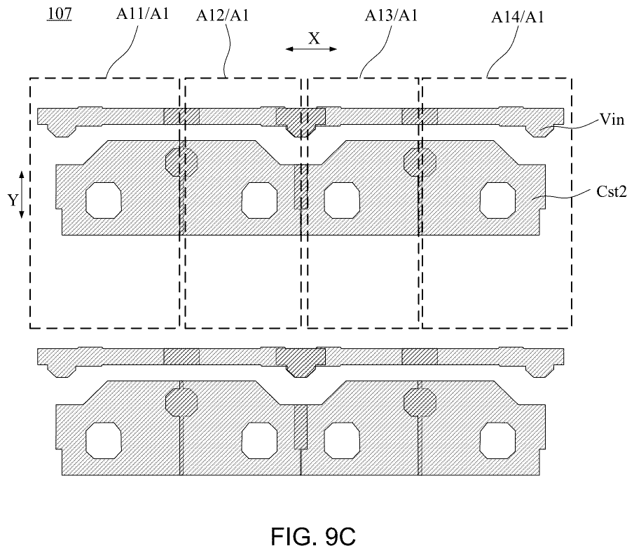

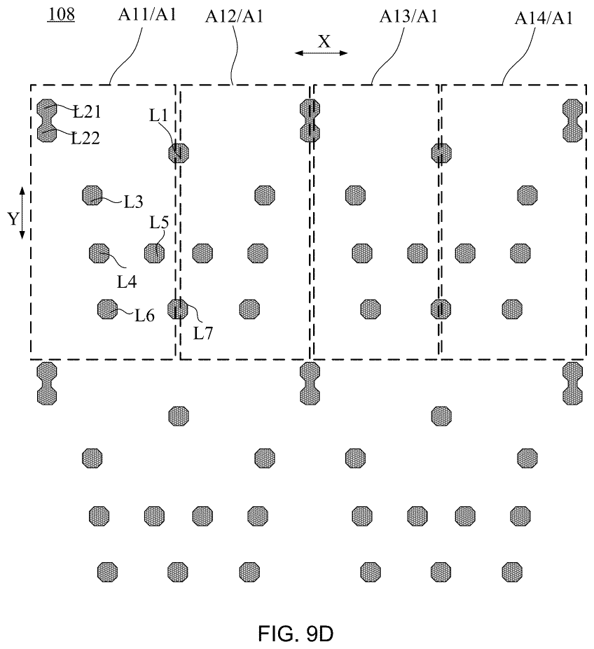

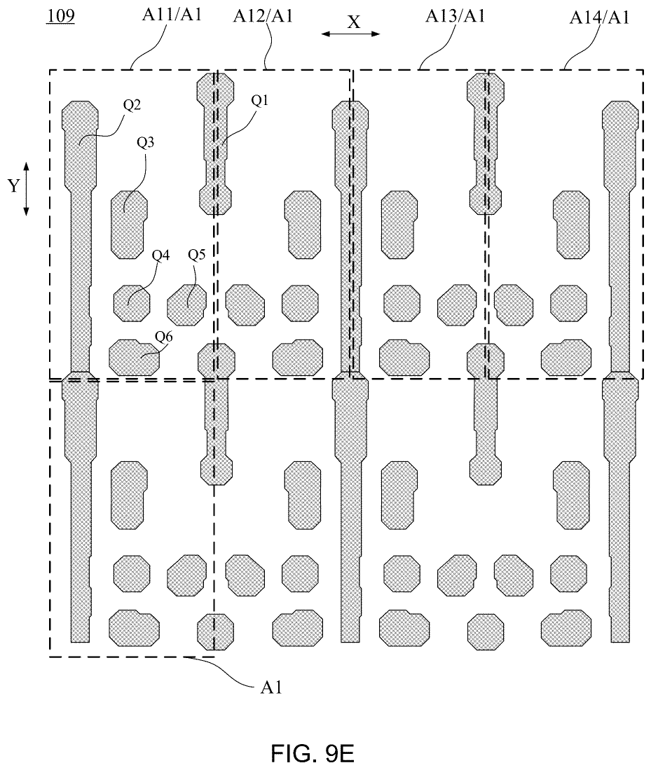

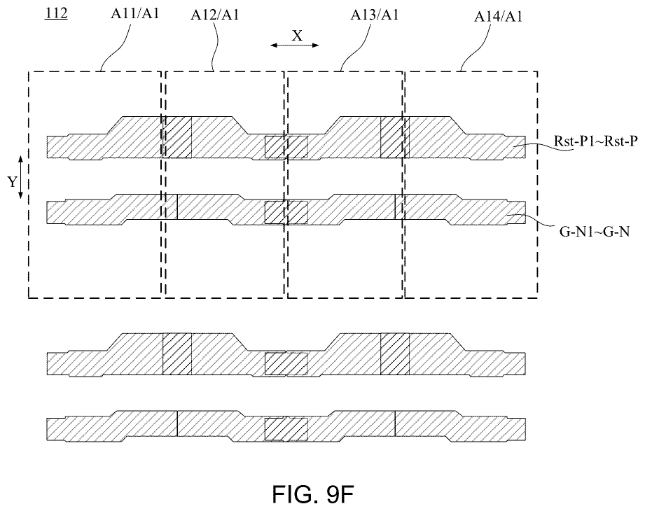

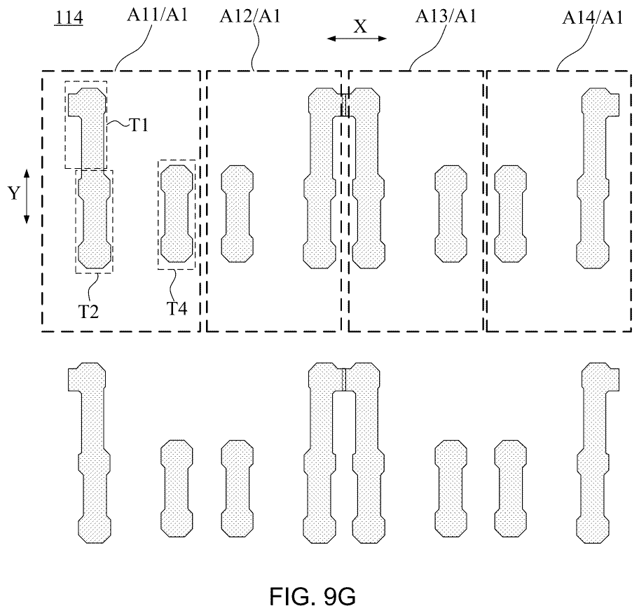

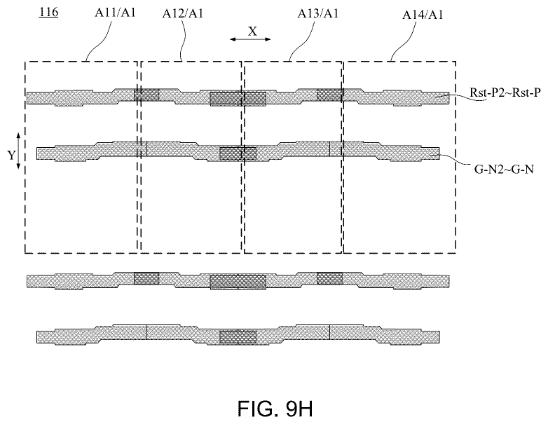

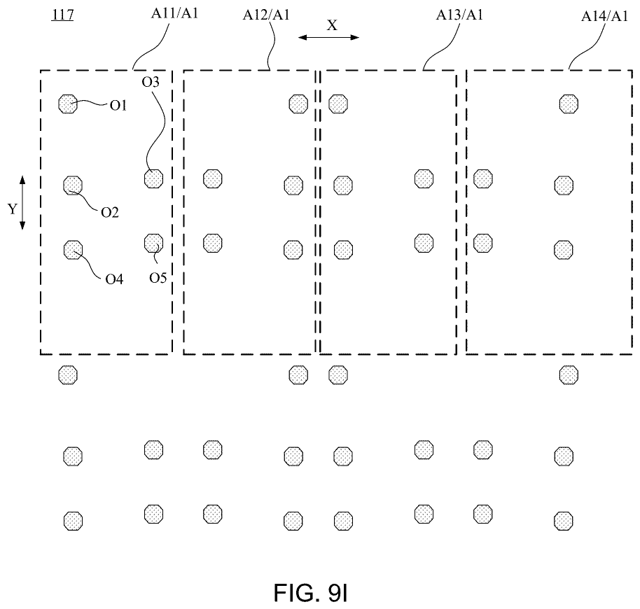

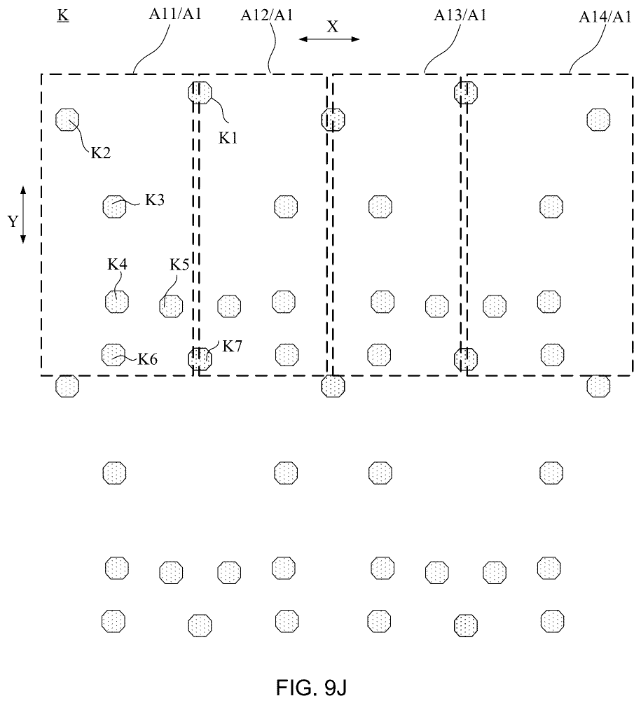

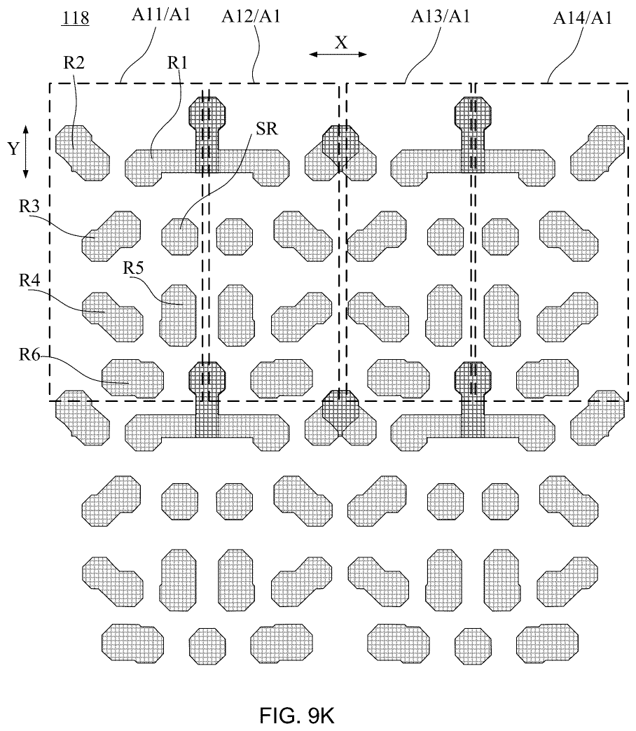

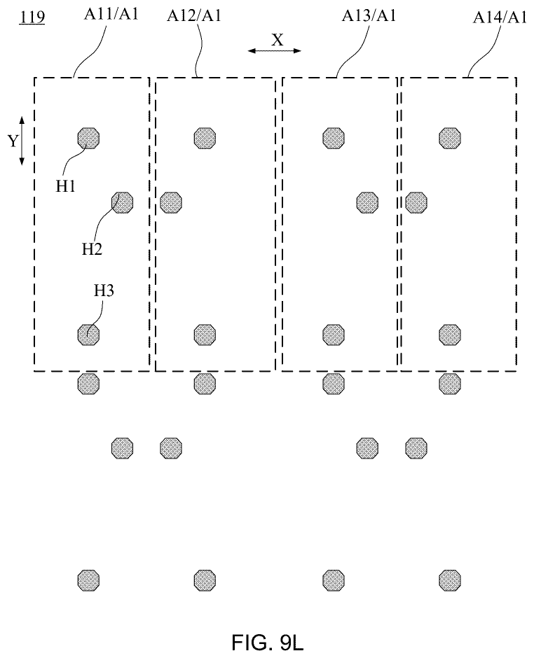

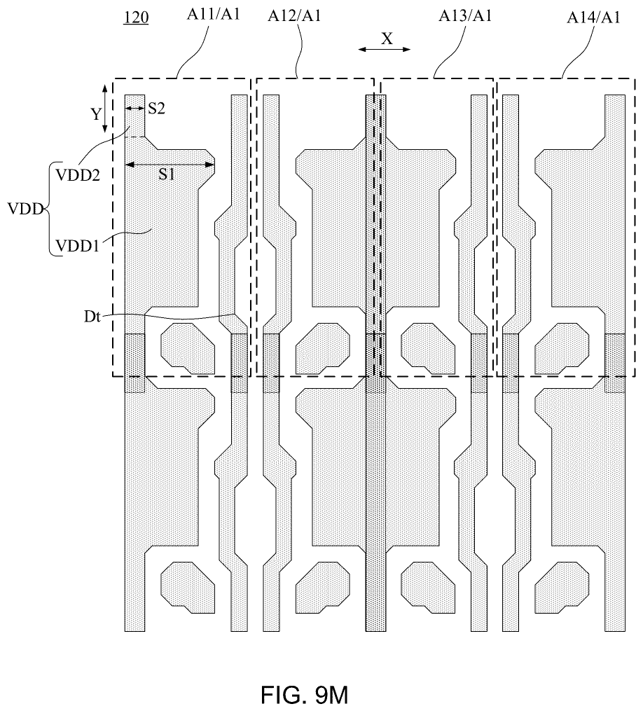

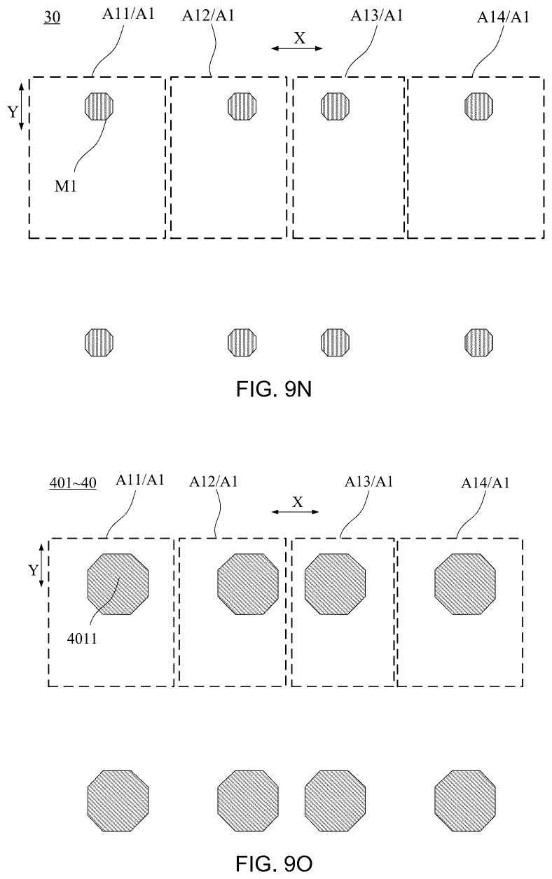

In some embodiments, referring to FIG. 8 and FIGS. 9A to 9O, the four adjacent sub-pixel regions A1 in a row direction (i.e., the first direction) are a first sub-pixel region A11, a second sub-pixel region A12, a third sub-pixel region A13 and a fourth sub-pixel region A14, film layer patterns in every two adjacent sub-pixel regions A1 are arranged in a mirror-image manner.

For example, referring to FIG. 8, FIG. 8 being a diagram showing a stacked arrangement structure of film layers in four adjacent sub-pixel regions A1 in the row direction; the film layer patterns in two adjacent sub-pixel regions A1 are arranged in a mirror-image manner; that is, the film layer patterns in the first sub-pixel region A11 and the film layer patterns in the second sub-pixel region A12 are arranged in a mirror-image manner in the row direction, the film layer patterns in the second sub-pixel region A12 and the film layer patterns in the third sub-pixel region A13 are arranged in the row direction, the film layer patterns in the third sub-pixel region A13 and the film layer patterns in the fourth sub-pixel region A14 are arranged in a mirror-image manner in the row direction. Moreover, the film layer patterns of each type in two adjacent sub-pixel regions A1 are arranged in a mirror-image manner. For example, the first active film layer in the first sub-pixel region A11 and the first active film layer in the second sub-pixel region A12 are arranged in a mirror-image manner in the row direction, and the first source-drain metal layer in the first sub-pixel region A11 and the first source-drain metal layer in the second sub-pixel region A12 are arranged in a mirror-image manner in the row direction. With such the arrangement of a mirror-image manner, it is possible to reduce the total area of the plurality of sub-pixel regions A1 to further reduce the space occupied by the plurality of sub-pixels, which is beneficial to improving the PPI of the display panel and simplifying the pattern design of each film layer.

In some embodiments, referring to FIG. 9A, the active layer pattern of the first light-emitting control transistor T5 in the first sub-pixel region A11 overlaps with the active layer pattern of the first light-emitting control transistor T5 in the second sub-pixel region A12, the active layer pattern of the second reset transistor T7 in the second sub-pixel region A12 overlaps with the active layer pattern of the second reset transistor T7 in the third sub-pixel region A13.

For example, referring to FIG. 9A, the active layer pattern of the first light-emitting control transistor T5 in the first sub-pixel region A11 and the active layer pattern of the first light-emitting control transistor T5 in the second sub-pixel region A12 are set to have an overlapping portion, and the overlapping portion is referred to as a first overlapping portion J1; the active layer pattern of the second reset transistor T7 in the second sub-pixel region A12 and the active layer pattern of the second reset transistor T7 in the third sub-pixel region A13 are set to have an overlapping portion, and the overlapping portion is referred to as a second overlapping portion J2. It will be understood that, any two adjacent sub-pixel regions A1 have an overlapping portion, and the overlapping portion is the first overlapping portion J1 or the second overlapping portion J2. Due to the provision of the first overlapping portion J1 and the second overlapping portion J2, it is possible to reduce the total area of the plurality of sub-pixel regions A1, thereby improving the PPI of the display panel; furthermore, during the process of forming via holes, it is possible to simplify the process by punching the via holes only once on the overlapping portion to realize the connection between the active layer patterns of the transistors in two adjacent sub-pixel regions and the corresponding signal line.

In some embodiments, referring to FIG. 9E, in the sub-pixel region A1, the first source-drain metal layer 109 includes a first bridging pattern Q1 and a second bridging pattern Q2; the first bridging pattern Q1 in the first sub-pixel region A11 coincides with the second bridging pattern Q2 in the second sub-pixel region A12, and the second bridging pattern Q2 in the second sub-pixel region A12 coincides with the second bridging pattern Q2 in the third sub-pixel region A13.

For example, as shown in FIG. 9E, the first bridging pattern Q1 in the first sub-pixel region A11 is set to coincide with the first bridging pattern Q1 in the second sub-pixel region A12, that is, the first bridging pattern Q1 may be shared by the first sub-pixel region A11 and the second sub-pixel region A12; similarly, referring to FIG. 9E, considering the four adjacent sub-pixel regions A1 as an example, it can be seen from the figure that the second bridging pattern Q2 in the second sub-pixel region A12 coincides with the second bridging pattern Q2 in the third sub-pixel region A13, and the second bridging pattern Q2 is able to be shared by the second sub-pixel region A12 and the third sub-pixel region A13. Accordingly, among a row of sub-pixel regions A1 arranged in the row direction, for other sub-pixel regions except for the first sub-pixel region A1 and the last sub-pixel region A1, any two adjacent sub-pixel regions A1 have an overlapping portion, and the overlapping portion is the first bridging pattern Q1 or the second bridging pattern Q2.

With such the above-mentioned arrangement for the first bridging pattern Q1 and the second bridging pattern Q2, it is possible to simplify the manufacturing process of the first source-drain metal layer 109, and reduce the area occupied by the two adjacent sub-pixel regions A1, thereby improving the PPI of the display panel.

In some embodiments, referring to FIG. 9E, the second bridging patterns Q2 in the sub-pixel regions A1 arranged in a column direction Y (i.e., the second direction Y) are connected in sequence.

It will be noted that, as shown in FIG. 9E, considering four adjacent sub-pixel regions A1 as an example, in the first sub-pixel region A11, the second sub-pixel region A12, the third sub-pixel region A13 and the fourth sub-pixel region A14 in the figure, the second bridging patterns Q2 are each extend in the column direction Y; and among the multiple sub-pixel regions A1 arranged in the column direction Y, the second bridging patterns Q2 in two adjacent sub-pixel regions A1 are connected to each other; that is, the second bridging patterns Q2 in the multiple sub-pixel regions A1 arranged in the column direction Y are connected in sequence to constitute a plurality of initialization signal bridging lines each extending in the column direction Y. With such the arrangement, it is possible to simplify the wiring of the first source-drain metal layer 109; moreover, the second bridging pattern Q2 is connected to the initialization signal line; the plurality of initialization signal lines are located in the second gate metal layer and each extend in the row direction X, and the plurality of initialization signal bridging lines are located in the first source-drain metal layer and each extend in the column direction Y, so that the lines used to transmit initialization signal form a grid-like structure, which facilitates signal transmission, improves signal transmission efficiency, and reduces transmission voltage drop, so that the uniformity of initialization signals in different sub-pixel regions is improved. As a result, it is conducive to the uniformity of reset of each pixel driving circuit, thereby improving the display effect of the screen.

In some embodiments, as shown in FIG. 9G, in the sub-pixel region A1, the active layer pattern of the first reset transistor T1 is connected to the active layer pattern of the compensation transistor T2, and the active layer pattern of the writing transistor T4 is located on a side of the active layer pattern of the compensation transistor T2 in the row direction X; the active layer pattern of the first reset transistor T1 in the second sub-pixel region A12 is connected to the active layer pattern of the first reset transistor T1 in the third sub-pixel region A13.

For example, referring to FIG. 9G, considering four adjacent sub-pixel regions A1 as an example, in each of the first sub-pixel region A11, the second sub-pixel region A12, the third sub-pixel region A13 and the fourth sub-pixel region A14, the active layer pattern of the first reset transistor T1 and the active layer pattern of the compensation transistor T2 are connected to each other and arranged in the column direction Y, and the active layer pattern of the writing transistor T4 is located on a side of the active layer pattern of the compensation transistor T2 in the row direction X. For example, in the first sub-pixel region A11 and the third sub-pixel region A13 shown in the FIG. 9G, the active layer pattern of the writing transistor T4 is located on a first side of the active layer pattern of the compensation transistor T2 in the row direction X; in the second sub-pixel region A12 and the fourth sub-pixel region A14 shown in the FIG. 9G, the active layer pattern of the writing transistor T4 is located on a second side of the active layer pattern of the compensation transistor T2 in the row direction X. Referring to FIG. 9G, the active layer pattern of the first reset transistor T1 in the second sub-pixel region A12 is connected to the active layer pattern of the first reset transistor T1 in the third sub-pixel region A13. With such the arrangement, it is possible to simplify the arrangement of the active layer patterns of the first reset transistors T1 and the corresponding circuits; that is, in the second sub-pixel region A12 and the third sub-pixel region A13, the line connecting to the active layer pattern of the first reset transistor T1 only need to be connected to the active layer pattern of the first reset transistor T1 in the second sub-pixel region A12 or the third sub-pixel region A13; furthermore, it is possible to reduce the total area of the plurality of sub-pixel regions A1, so as to further improve the PPI of the display panel.

In some embodiments, referring to FIG. 9K, the second source-drain metal layer 118 includes first transfer patterns R1 and second transfer patterns R2; the first transfer pattern R1 in the first sub-pixel region A11 overlaps with the first transfer pattern R1 in the second sub-pixel region A12; the second transfer pattern R2 in the second sub-pixel region A12 overlaps with the second transfer pattern R2 in the third sub-pixel region A13.

For example, as shown in FIG. 9K, the first transfer pattern R1 in the first sub-pixel region A11 is set to overlap with the first transfer pattern R1 in the second sub-pixel region A12, that is, the first transfer pattern R1 may be shared by the first sub-pixel region A11 and the second sub-pixel region A12; similarly, referring to FIG. 9K, considering four adjacent sub-pixel regions A1 as an example, it can be seen from the figure that, the second transfer pattern R2 in the second sub-pixel region A12 overlaps with the second transfer pattern R2 in the third sub-pixel region A13, and the second transfer pattern R2 may be shared by the second sub-pixel region A12 and the third sub-pixel region A13. Based on this, among a row of sub-pixel regions A1 arranged in the row direction X, in other sub-pixel regions except for the first sub-pixel region A1 and the last sub-pixel region A1, any two adjacent sub-pixel regions A1 have an overlapping portion, which is an overlapping portion between the first transfer pattern R1 and the first transfer pattern R1, or an overlapping portion between the second transfer pattern R2 and the second transfer pattern R2.

Compared with the related art in which the first transfer patterns R1 do not overlap and the second transfer patterns R2 do not overlap, the above arrangement of the first transfer patterns R1 and the second transfer patterns R2 has the function of simplifying the connection between the first transfer patterns R1 or the second transfer patterns R2 in the second source-drain metal layer 118 and other lines and, serves to connect with other circuits and can reduce the area occupied by two adjacent sub-pixel regions A1, thereby improving the PPI of the display panel.

In some embodiments, referring to FIG. 9M, the third source-drain metal layer 120 includes a plurality of first voltage signal lines VDD, each first voltage signal line VDD is located in a column of sub-pixel regions A1; the first voltage signal line VDD includes voltage patterns VDD1 and voltage sub-lines VDD2 that are alternately connected; a dimension S1 of the voltage pattern VDD1 in the row direction X is greater than a dimension S2 of the voltage sub-line VDD2 in the row direction X; the first voltage signal line VDD in the second sub-pixel region A12 overlaps with the first voltage signal line VDD in the third sub-pixel region A13.

For example, referring to FIG. 9M, the plurality of first voltage signal lines VDD are arranged in the column direction Y, and each first voltage signal line VDD is located in a column of sub-pixel regions A1. In the column direction Y, the first voltage signal line VDD includes voltage patterns VDD1 and voltage sub-lines VDD2 that are alternately connected. The dimension S1 of the voltage pattern VDD1 in the row direction X is set to be greater than the dimension S2 of the voltage sub-line VDD2 in the row direction X, which is mainly based on the requirement of spatial arrangement; moreover, it is possible to reduce the resistance and improve the transmission efficiency of the first voltage signal line VDD. In addition, the voltage pattern VDD1 is block-shaped, which may improve the flatness of this region and is beneficial to the flatness of the film pattern (e.g. the anode layer) located on the voltage pattern VDD1.

Referring to FIG. 9M, the first voltage signal line VDD in the second sub-pixel region A12 is set to overlap with the first voltage signal line VDD in the third sub-pixel region A13, it is possible to reduce the area occupied by the sub-pixel region A1 to improve the PPI of the display panel; in addition, it is possible to simplify the connection between the first voltage signal lines VDD in the third source-drain metal layer 120 and other lines; since the first voltage signal lines VDD in the second sub-pixel region A12 and the third sub-pixel region A13 may both play a role in transmitting the first voltage signal, there is no need to be connected to both the first voltage signal line VDD in the second sub-pixel region A12 and the first voltage signal line VDD in the third sub-pixel region A13, just choose one of the two to be connected.

In some embodiments, as shown in FIG. 4, the array substrate 10 further includes a first planarization layer 110 disposed between the first source-drain metal layer 109 and the third gate metal layer 112, and the thickness of the first planarization layer 110 is in a range of 1.5 μm to 2 μm, inclusive.

It will be noted that, the first planarization layer 110 is disposed between the first source-drain metal layer 109 and the third gate metal layer 112, it is possible to ensure that the second-type transistors T0′ have a flat bottom; the thickness of the first planarization layer 110 is set to be in a range of 1.5 μm to 2 μm, and the thickness is great, which may play a certain isolation role between the first-type transistors T0 and the second-type transistors T0′, and reduces the parasitic capacitance between the first-type transistors T0 and the second-type transistors T0′, thereby avoiding the signal interference between the transistors.

In some embodiments, as shown in FIGS. 4, 6L and 7A, the array substrate 10 further includes a second planarization layer 119 disposed between the second source-drain metal layer 118 and the third source-drain metal layer 120. The third source-drain metal layer 120 is connected to the second source-drain metal layer 118 through via holes penetrating through the second planarization layer 119.

For example, referring to FIG. 6L, the second planarization layer 119 is provided with a plurality of first-type via holes H therein, and the first-type via holes H include a first-type via hole H1, a first-type via hole H2 and a first-type via hole H3. Referring to FIG. 7A, the third source-drain metal layer 120 is connected to the second source-drain metal layer 118 through the first-type via hole H1 penetrating through the second planarization layer 119, so that the first voltage signal from the first voltage signal line VDD in the third source-drain metal layer 120 is transmitted to the first transfer pattern R1 of the second source-drain metal layer 118.

Some embodiments of the present disclosure provide a display panel 100, and the display panel 100 includes the array substrate 10 provided in any of the above embodiments. Therefore, the display panel 100 provided by the embodiments of the present disclosure has all the beneficial effects of the array substrate 10 provided by any of the above embodiments, which will not be described again here.

In some embodiments, referring to FIG. 4, the display panel 100 further includes a third planarization layer 30, a light-emitting device layer 40 and an encapsulation layer that are arranged on the array substrate 10. The array substrate 10 includes a base substrate 101 and a pixel circuit stack layer 20. The pixel circuit stack layer 20 includes a plurality of transistors. The third planarization layer 30, the light-emitting device layer 40 and the encapsulation layer are sequentially stacked on the pixel circuit stack layer 20.

The light-emitting device layer 40 includes an anode layer 401, a pixel definition layer 402, a light-emitting layer 403, and a cathode layer.

Referring to FIGS. 4, 6N and 6O, the array substrate 10 includes a third source-drain metal layer 120, the third planarization layer 30 is disposed on a side of the third source-drain metal layer 120 away from the base substrate, and the anode layer 401 is disposed on the third planarization layer 30. The anode layer 401 includes a plurality of anodes 4011, and the plurality of anodes 4011 are electrically connected to the third source-drain metal layer 120 through via holes M1 penetrating through the third planarization layer 30. The light-emitting layer 403 includes a plurality of light-emitting portions, and each light-emitting portion overlaps with an anode 4011. The pixel definition layer 402 is provided with a plurality of pixel openings therein, and each pixel opening exposes a portion of an anode 4011, and the light-emitting portions in the light-emitting layer 403 are arranged in the pixel openings in one-to-one correspondence, so that the edge of the light-emitting portion coincides with the edge of the pixel opening.

The cathode layer 4 is located on a side of the pixel definition layer 402 and the light-emitting layer 403 away from the array substrate 10.

The light-emitting device OLED shown in FIGS. 4 and 5A includes an anode and a cathode, and a light-emitting layer between the anode and the cathode. Voltages are respectively applied to the anode and cathode to generate an electric field therebetween, so that the holes in the anode and the electrons in the cathode may be driven to recombine in the light-emitting layer, to enable the light-emitting layer to emit light. The anode 4011 is disposed on the array substrate 10 and may be electrically connected to the pixel driving circuit 200.

As shown in FIG. 4, the display panel 100 further includes spacers PS, and the spacers PS are used to support a fine metal mask (FMM) during evaporation of the light-emitting layer.

The encapsulation layer is located on the side of the cathode layer away from the array substrate 10. For example, the encapsulation layer includes a first inorganic encapsulation layer, an organic encapsulation layer and a second inorganic encapsulation layer. The encapsulation layer is used to encapsulate the light-emitting devices to protect the light-emitting devices, thereby avoiding corrosion caused by external moisture and oxygen.

Some embodiments of the present disclosure provide a display device 1000, and the display device may be a television, a mobile phone, a tablet computer, a personal digital assistant (PDA), an in-vehicle computer, or a wearable display device. The embodiments of the present disclosure do not particularly limit a specific form of the display device. As shown in FIG. 1, the display device 1000 includes the display panel 100 provided by any of the above embodiments. Therefore, the display device 1000 provided by the embodiments of the present disclosure has all the beneficial effects of the display panel 100 provided by any of the above embodiments, which will not be repeated here.

The above are only specific embodiments of the present disclosure, but the scope of protection of the present disclosure is not limited thereto, and any person skilled in the art may conceive of variations or replacements within the technical scope of the present disclosure, which shall fall within the protection scope of the present disclosure. Therefore, the protection scope of the present disclosure should be determined by the protection scope of the claims.

1. An array substrate, comprising a plurality of sub-pixel regions, each sub-pixel region being provided with a pixel driving circuit therein, a plurality of pixel driving circuits being arranged in rows and columns, the pixel driving circuit including a plurality of first-type transistors and a plurality of second-type transistors, and the plurality of second-type transistors including at least a writing transistor; wherein
the array substrate comprises:
a base substrate;
a first active film layer disposed on a side of the base substrate, the first active film layer including active layer patterns of the plurality of first-type transistors;
a second active film layer disposed on a side of the first active film layer away from the base substrate, the second active film layer including an active layer pattern of the writing transistor; and
a third source-drain metal layer disposed on a side of the second active film layer away from the base substrate, the third source-drain metal layer including data signal lines, and the active layer pattern of the writing transistor being electrically connected to a data signal line.

2. The array substrate according to claim 1, wherein the array substrate further comprises:
a first source-drain metal layer disposed between the first active film layer and the second active film layer; and
a second source-drain metal layer disposed between the second active film layer and the third source-drain metal layer; wherein
in the sub-pixel region, the second source-drain metal layer includes a data line transfer pattern; the data signal line is connected to the data line transfer pattern through a via hole, and the data line transfer pattern is connected to the active layer pattern of the writing transistor.

3. The array substrate according to claim 2, wherein the pixel driving circuit further includes a capacitor; wherein
the array substrate further comprises:
a first gate metal layer and a second gate metal layer that are sequentially arranged on the side of the first active film layer away from the base substrate; wherein
in the sub-pixel region, the first gate metal layer includes a first plate pattern of the capacitor, and the second gate metal layer includes a second plate pattern of the capacitor;
the third source-drain metal layer further includes first voltage signal lines;
in the sub-pixel region, the second source-drain metal layer further includes a first transfer pattern, and the first source-drain metal layer includes a first bridging pattern; and
a first voltage signal line is connected to the first transfer pattern in the second source-drain metal layer through a via hole, and the first transfer pattern is connected to the first bridging pattern in the first source-drain metal layer through another via hole, and the first bridging pattern is connected to the second plate pattern in the second gate metal layer through yet another via hole, so that the first voltage signal line is electrically connected to the second plate pattern.

4. The array substrate according to claim 1, wherein the second-type transistors further include a first reset transistor and a compensation transistor, and the first-type transistors include a driving transistor, a first light-emitting control transistor, a second light-emitting control transistor and a second reset transistor; wherein
the first active film layer includes an active layer pattern of the driving transistor, an active layer pattern of the first light-emitting control transistor, an active layer pattern of the second light-emitting control transistor, and an active layer pattern of the second reset transistor; the second active film layer further includes an active layer pattern of the first reset transistor and an active layer pattern of the compensation transistor.

5. The array substrate according to claim 4, further comprising:
a first source-drain metal layer disposed between the first active film laver and the second active film layer.
a third gate metal layer disposed between the first source-drain metal layer and the second active film layer; and
a fourth gate metal layer disposed on a side of the second active film layer away from the third gate metal layer;
wherein the third gate metal layer includes a first reset signal line first branch line and a scanning signal line first branch line; the first reset signal line first branch line passes through the active layer pattern of the first reset transistor, and the scanning signal line first branch line passes through both the active layer pattern of the compensation transistor and the active layer pattern of the writing transistor;
the fourth gate metal layer includes a first reset signal line second branch line and a scanning signal line second branch line; the first reset signal line second branch line passes through the active layer pattern of the first reset transistor, and the scanning signal line second branch line passes through both the active layer pattern of the compensation transistor and the active layer pattern of the writing transistor;
the first reset signal line first branch line is electrically connected to the first reset signal line second branch line, and the scanning signal line first branch line is electrically connected to the scanning signal line second branch line.

6. The array substrate according to claim 4, wherein the array substrate further comprises: a second gate metal layer disposed on the side of the first active film layer away from the base substrate, a first source-drain metal layer disposed between the first active film layer and the second active film layer, and a second source-drain metal layer disposed between the second active film layer and the third source drain metal layer, wherein
the second gate metal layer includes a plurality of initialization signal lines;
in the sub-pixel region, the first source-drain metal layer includes a second bridging pattern, and the second source-drain metal layer includes a second transfer pattern;
wherein the second bridging pattern is electrically connected to the active layer pattern of the second reset transistor and an initialization signal line through two via holes, so that the active layer pattern of the second reset transistor is electrically connected to the initialization signal line; and
the second transfer pattern is connected to the second bridging pattern and the active layer pattern of the first reset transistor through another two via holes, so that the active layer pattern of the first reset transistor is electrically connected to the initialization signal line.

7. The array substrate according to claim 6, wherein the array substrate further comprises a first gate metal layer disposed between the first active film layer and the second gate metal layer; wherein in the sub-pixel region, the first source-drain metal layer further includes a third bridging pattern, and the second source-drain metal layer further includes a third transfer pattern; wherein
the third bridging pattern is connected to a first plate pattern of a capacitor in the first gate metal layer through a via hole, the third transfer pattern is connected to the third bridging pattern through another via hole, and the active layer pattern of the compensation transistor in the second active film layer is connected to the third transfer pattern through yet another via hole, so that the compensation transistor is electrically connected to the first plate pattern; and/or
in the sub-pixel region, the first source-drain metal layer further includes a fourth bridging pattern, and the second source-drain metal layer includes a fourth transfer pattern; wherein
the fourth bridging pattern is connected to the active laver pattern of the second light-emitting control transistor in the first active film laver through a via hole;
the fourth transfer pattern is connected to the fourth bridging pattern through a via hole, and the active layer pattern of the compensation transistor in the second active film laver is connected to the fourth transfer pattern through another vis hole, so that the compensation transistor is electrically connected to the second light-emitting control transistor.

8. (canceled)

9. The array substrate according to claim 6, wherein in the sub-pixel region, the first source-drain metal layer further includes a fifth bridging pattern, and the second source-drain metal layer further includes a fifth transfer pattern; wherein
the fifth bridging pattern is connected to the active layer pattern of the first light-emitting control transistor in the first active film layer through a via hole; and
the fifth transfer pattern is connected to the fifth bridging pattern through another via hole, and the active layer pattern of the writing transistor in the second active film layer is connected to the fifth transfer pattern through yet another via hole, so that the writing transistor is electrically connected to the first light-emitting control transistor; and/or
in the sub-pixel region, the first source-drain metal layer further includes a sixth bridging pattern, and the second source-drain metal layer further includes a sixth transfer pattern; wherein
the sixth bridging pattern is connected to the active layer pattern of the second light-emitting control transistor in the first active file laver through a via hole, and the sixth transfer pattern is connected to the sixth bridging pattern.

10. (canceled)

11. The array substrate according to claim 1, wherein four adjacent sub-pixel regions in a row direction are respectively a first sub-pixel region, a second sub-pixel region, a third sub-pixel region and a fourth sub-pixel region, wherein film layer patterns in every two adjacent sub-pixel regions are arranged in a mirror-image manner.

12. The array substrate according to claim 11, wherein the first-type transistors include a first light-emitting control transistor a second reset transistor, wherein
an active layer pattern of a first light-emitting control transistor in the first sub-pixel region overlaps with an active layer pattern of a first light-emitting control transistor in the second sub-pixel region, and an active layer pattern of a second reset transistor in the second sub-pixel region overlaps with an active layer pattern of a second reset transistor in the third sub-pixel region.

13. The array substrate according to claim 11, further comprising a first source-drain metal layer disposed between the first active film layer and the second active film layer, wherein in the sub-pixel region, the first source-drain metal layer includes a first bridging pattern and a second bridging pattern, wherein
a first bridging pattern in the first sub-pixel region coincides with a first bridging pattern in the second sub-pixel region, and a second bridging pattern in the second sub-pixel region coincides with a second bridging pattern in the third sub-pixel region.

14. The array substrate according to claim 13, wherein second bridging patterns in sub-pixel regions arranged in a column direction are connected in sequence.

15. The array substrate according to claim 11, wherein the second-type transistors further include a first reset transistor and a compensation transistor, and the second active film layer further includes an active layer pattern of the first reset transistor and an active layer pattern of the compensation transistor, wherein
in the sub-pixel region, the active layer pattern of the first reset transistor is connected to the active layer pattern of the compensation transistor, and the active layer pattern of the writing transistor is located on a side of the active layer pattern of the compensation transistor in the row direction; wherein
an active layer pattern of a first reset transistor in the second sub-pixel region is connected to an active layer pattern of a first reset transistor in the third sub-pixel region.

16. The array substrate according to claim 11, wherein the array substrate further comprises: a second source-drain metal layer disposed between the second active film layer and the third source-drain metal layer, wherein the second source-drain metal layer includes first transfer patterns and second transfer patterns, wherein
a first transfer pattern in the first sub-pixel region overlaps with a first transfer pattern in the second sub-pixel region, and a second transfer pattern in the second sub-pixel region overlaps with a second transfer pattern in the third sub-pixel region; and/or
the third source-drain a metal ay incl es alit first voltage signal lines, and each first voltage signal line is located in a column of sub pixel regions; wherein the first voltage signal line includes voltage patterns and voltage sub-lines that are alternately connected, a dimension of a voltage pattern in the row direction is greater than a dimension of a voltage sub-live in the row direction; wherein
a first voltage signal line in the second sub pixel region overlaps with a first voltage signal line in the third sub pixel region.

17. (canceled)

18. The array substrate according to claim 5, further comprising: a first planarization layer disposed between the first source-drain metal layer and the third gate metal layer, wherein a thickness of the first planarization layer is in a range of 1.5 μm to 2 μm, inclusive.

19. The array substrate according to claim 2, further comprising: a second planarization layer disposed between the second source-drain metal layer and the third source-drain metal layer, wherein the third source-drain metal layer is connected to the second source-drain metal layer through a via hole penetrating through the second planarization layer.

20. The array substrate according to claim 1, wherein the first active film layer is a low temperature polysilicon layer, and the second active film layer is an oxide layer.

21. A display panel, comprising the array substrate according to claim 1.

22. The display panel according to claim 21, further comprising:
a third planarization layer disposed on a side of the third source-drain metal layer away from the base substrate;
an anode layer disposed on the third planarization layer, the anode layer including a plurality of anodes;
a pixel definition layer disposed on a side of the anode layer away from the base substrate; and
spacers disposed on a side of the pixel definition layer away from the base substrate;
wherein the plurality of anodes are electrically connected to the third source-drain metal layer through via holes penetrating through the third planarization layer.

23. A display device, comprising: the display panel according to claim 21.
